(19) United States
(12) Patent Application Publication
(10) Pub. No.: US 2012/0235116 A1
(43) Pub. Date: Sep. 20, 2012

(54) LIGHT EMITTING DIODE WITH ENHANCED QUANTUM EFFICIENCY AND METHOD OF FABRICATION

(76) Inventors: Jie Su, Edison, NJ (US); Olga Kryliouk, Sunnyvale, CA (US); Yuriy Melnik, Santa Clara, CA (US); Hidehiro Kojiri, Sunnyvale, CA (US); Lu Chen, Sunnyvale, CA (US); Tetsuya Ishikawa, Saratoga, CA (US)

(21) Appl. No.: 13/387,713

(22) PCT Filed: Jul. 30, 2010
(86) PCT No.: PCT/US10/43993

§ 371 Date: Apr. 9, 2012

Related U.S. Application Data
(60) Provisional application No. 61/230,438, filed on Jul. 31, 2009.
(60) Provisional application No. 61/263,735, filed on Nov. 23, 2009.

(51) Int. Cl. H01L 33/04; C30B 25/02; H01B 1/02; C30B 25/08

(52) U.S. Cl. 257/13; 438/47; 118/729; 117/88; 420/591; 252/512; 257/E33.008

(57) ABSTRACT

One embodiment of a quantum well structure comprises an active region including active layers that comprise quantum wells and barrier layers wherein some or all of the active layers are p type doped. P type doping some or all of the active layers improves the quantum efficiency of III-V compound semiconductor light emitting diodes by locating the position of the P-N junction in the active region of the device thereby enabling the dominant radiative recombination to occur within the active region. In one embodiment, the quantum well structure is fabricated in a cluster tool having a hydride vapor phase epitaxial (HVPE) deposition chamber with a eutectic source alloy. In one embodiment, the indium gallium nitride (InGaN) layer and the magnesium doped gallium nitride (Mg—GaN) or magnesium doped aluminum gallium nitride (Mg—AlGaN) layer are grown in separate chambers by a cluster tool to avoid indium and magnesium cross contamination. Doping of group III-nitrides by hydride vapor phase epitaxy using group III-metal eutectics is also described. In one embodiment, a source is provided for HVPE deposition of a p-type or an n-type group III-nitride epitaxial film, the source including a liquid phase mechanical (eutectic) mixture with a group III species. In one embodiment, a method is provided for performing HVPE deposition of a p-type or an n-type group III-nitride epitaxial film, the method including using a liquid phase mechanical (eutectic) mixture with a group III species.

### CROSS REFERENCE TO RELATED APPLICATIONS

This application claims the benefit of U.S. Provisional Application No. 61/230,438, filed Jul. 31, 2009 and U.S. Provisional Application No. 61/263,735, filed Nov. 23, 2009, the entire contents of which are hereby incorporated by reference herein.

### BACKGROUND

1. Field

Embodiments of the present invention relate to light emitting diodes with enhanced quantum efficiency and their methods of fabrication.

2. Discussion of Related Art

Light emitting diodes (LEDs) are the ultimate light source in lighting technology. The LED technology has flourished for the past few decades. High efficiency, reliability, rugged construction, low power consumption, and durability are among the key factors for the rapid development of the solid-state lighting based on high-brightness visible LEDs. Conventional light sources, such as filament light bulbs or fluorescent lamps depend on either incandescence or discharge in gases. These two processes are accompanied by large energy losses, which are attributed to high temperatures and large Stokes shift characteristics. On the other hand, semiconductors allow an efficient way of light generation. LEDs made of semiconductor materials have the potential of converting electricity to light with near unity efficiency. The example of a typical gallium nitride (GaN) based light emitting diodes (LEDs) is illustrated in FIG. 1. The LED structure includes a substrate 102 having an active region 104 sandwiched between a n-type contact layer 106, such as a silicon doped gallium nitride (Si—GaN) layer and a p-type contact layer 108, such as a magnesium doped gallium nitride (Mg—GaN) layer. The active region generally comprises one or more indium gallium nitride (InGaN) or aluminum gallium nitride (AlGaN) quantum well layers 120 and a plurality of barrier layers 122, such as gallium nitride (GaN) layers, to create a multi-quantum well (MQW) device. LED structure 100 generally includes a magnesium doped electron blocking layer (EBL) 110, such as a Mg—AlGaN layer, to effectively confine the radiative recombination within the active region.

The gallium nitride (GaN) barrier layers 122 in the active region are generally doped with silicon to improve the LED performance. Silicon doping improves the crystal interface qualities of the MQWs and coulomb screening of the piezoelectric field due to polarization. Unfortunately, the silicon doping in the MQW active region shifts the P-N junction position from the MQW region (or the interface between the last InGaN well and the EBL layer) into the EBL layer 110 or even the p type contact layer 108. As a result, holes can barely travel into the active region. Consequently, the dominant radiative recombination occurs within the EBL layer 110 or the p type contact resulting in a low internal quantum efficiency (IQE) and deviated wavelength.

### BRIEF DESCRIPTION OF THE DRAWINGS

FIG. 1 is an illustration of a conventional gallium nitride LED with silicon doped barriers.

FIG. 2A is an illustration of a LED with a p-type barrier in accordance with an embodiment of the present invention.

FIG. 2B is an illustration of a gallium nitride LED with magnesium doped barriers in accordance with an embodiment of the present invention.

FIG. 2C is an illustration of a LED structure having p-type barrier layers and p-type quantum wells in accordance with an embodiment of the present invention.

FIG. 2D is an illustration of an LED structure having p-type barrier layers and n-type barrier layers in accordance with an embodiment of the present invention.

FIG. 2E is an illustration of an LED structure having p-type barrier layers, n-type barrier layers and intermediate undoped barrier layers in accordance with an embodiment of the present invention.

FIG. 2F is an illustration of an LED structure having a p-type barrier layer adjacent to the electron blocking layer and an n-type barrier layer adjacent to the n-type contact layer and undoped central barrier layers in accordance with an embodiment of the present invention.

FIG. 3 illustrates the junction position of a LED device having magnesium doped barriers and the junction position of an LED device having silicon doped barriers.

FIG. 4 is an illustration of electron concentration and hole concentration for an LED device having magnesium doped barriers and silicon doped barriers.

FIG. 5 is an illustration of the radiative recombination of LED devices having silicon doped barriers and magnesium doped barriers.

FIG. 6 is a table which compares the IQE radiative recombination and hole concentration for LED devices having silicon doped barriers, half magnesium doped barriers and all magnesium doped barriers.

FIG. 7 is an isometric view illustrating a processing system according to an embodiment of the invention.

FIG. 8 is a plan view of the processing system illustrated in FIG. 7.

FIG. 9 is an isometric view illustrating a load station and loadlock chamber according to an embodiment of the invention.

FIG. 10 is a schematic view of a loadlock chamber according to an embodiment of the invention.

FIG. 11 is an isometric view of a carrier plate according to an embodiment of the invention.

FIG. 12 is a schematic view of a batch loadlock chamber according to an embodiment of the invention.

FIG. 13 is an isometric view of a work platform according to an embodiment of the invention.

FIG. 14 is a plan view of a transfer chamber according to an embodiment of the invention.

FIG. 15 is a schematic cross-sectional view of a HVPE chamber according to an embodiment of the invention.

FIG. 16 is a schematic cross-sectional view of an MOCVD chamber according to an embodiment of the invention.

FIG. 17 is a schematic view illustrating another embodiment of a processing system for fabricating compound nitride semiconductor devices.

FIG. 18 is a schematic view illustrating yet another embodiment of a processing system for fabricating compound nitride semiconductor devices.

FIG. 19 illustrates a plot of temperature as a function of a ratio of species A and B in a eutectic, in accordance with an embodiment of the present invention.

FIG. 20 illustrates, in a periodic table format, a variety of gallium binary systems, in accordance with an embodiment of the present invention.

FIG. 21 illustrates an exemplary magnesium-gallium (Mg—Ga) phase diagram used for selecting an appropriate eutectic mixture for HVPE deposition, in accordance with an embodiment of the present invention.

FIG. 22 depicts an XPS spectrum confirming that magnesium incorporation was achieved in a gallium nitride film, in accordance with an embodiment of the present invention.

FIG. 23 is a SIMS spectrum representative of a depth profile in a magnesium-doped p-type gallium nitride film formed from a gallium:magnesium eutectic, in accordance with an embodiment of the present invention.

FIG. 24 illustrates a temperature-composition phase diagram for mechanical mixtures of gallium with beryllium, in accordance with an embodiment of the present invention.

FIG. 25 illustrates a temperature-composition phase diagram for mechanical mixtures of gallium with calcium, in accordance with an embodiment of the present invention.

FIG. 26A illustrates a temperature-composition phase diagram for mechanical mixtures of gallium with strontium, in accordance with an embodiment of the present invention.

FIG. 26B illustrates a temperature-composition phase diagram for mechanical mixtures of gallium with magnesium, in accordance with an embodiment of the present invention.

FIG. 26C illustrates a temperature-composition phase diagram for mechanical mixtures of gallium with copper, in accordance with an embodiment of the present invention.

FIG. 26D illustrates a temperature-composition phase diagram for mechanical mixtures of gallium with copper, in accordance with an embodiment of the present invention.

FIG. 27 is a schematic view of an HVPE apparatus, in accordance with an embodiment of the present invention.

### DETAILED DESCRIPTION OF THE PRESENT INVENTION

In the following description, numerous specific details are set forth, such as fabrication conditions and material regimes, in order to provide a thorough understanding of embodiments of the present invention. It will be apparent to one skilled in the art that embodiments of the present invention may be practiced without these specific details. In other instances, well-known features, such as facility layouts or specific tool configurations, are not described in detail in order to not unnecessarily obscure embodiments of the present invention. Furthermore, it is to be understood that the various embodiments shown in the Figures are illustrative representations and are not necessarily drawn to scale. Additionally, other arrangements and configurations may not be explicitly disclosed in embodiments herein, but are still considered to be within the spirit and scope of the invention.

Embodiments of the present invention, improve the quantum efficiency of III-V compound semiconductor light emitting diodes (LEDs) by p type doping some or all of the barrier layers in a multiple quantum well device. P type doping some or all of the barrier layers locates the position of the P-N junction in the active region of the device thereby enabling the dominant radiative recombination to occur within the active region and thereby improve the quantum efficiency of the device. The p type dopant may be any element having at least two valence electrons. In a specific embodiment of the present invention, the p type dopant is magnesium (Mg). Additionally, in some embodiments of the present invention, not only are some or all of the barrier layers p type doped, but so are some or all of the quantum wells. In an embodiment of the present invention, the LED device is fabricated in a cluster tool having a metal organic chemical vapor deposition (MOCVD) chamber and hydride vapor phase epitaxial (HVPE) deposition chamber and/or a plasma assisted MOCVD chamber. In this way, the quantum well layers, such as an indium gallium nitride (InGaN) layer can be formed in one process chamber, such as MOCVD, plasma assisted MOCVD, or by HVPE and the p type doped barrier layers can be formed in another process chamber to avoid indium (In) and magnesium (Mg) cross contamination in a single chamber. In accordance with an embodiment of the present invention, doping of group III-nitrides by hydride vapor phase epitaxy using group III-metal eutectics is also described.

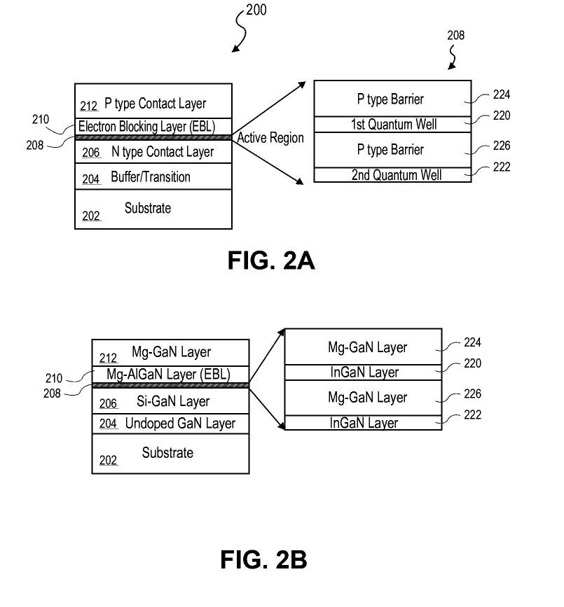

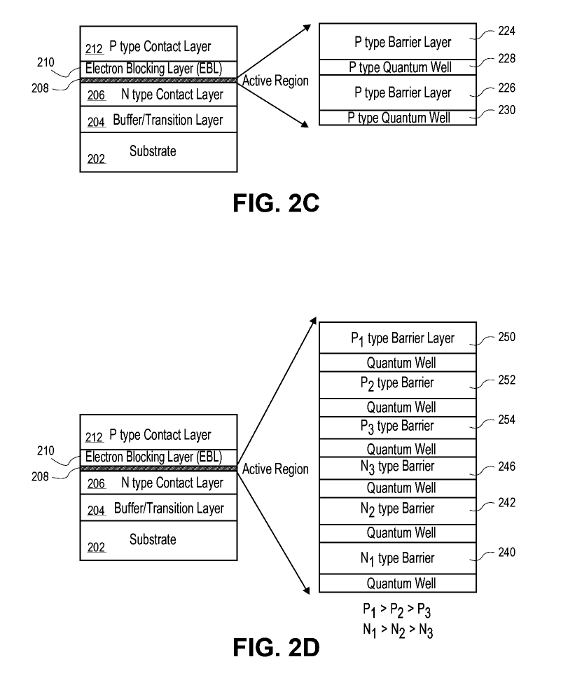

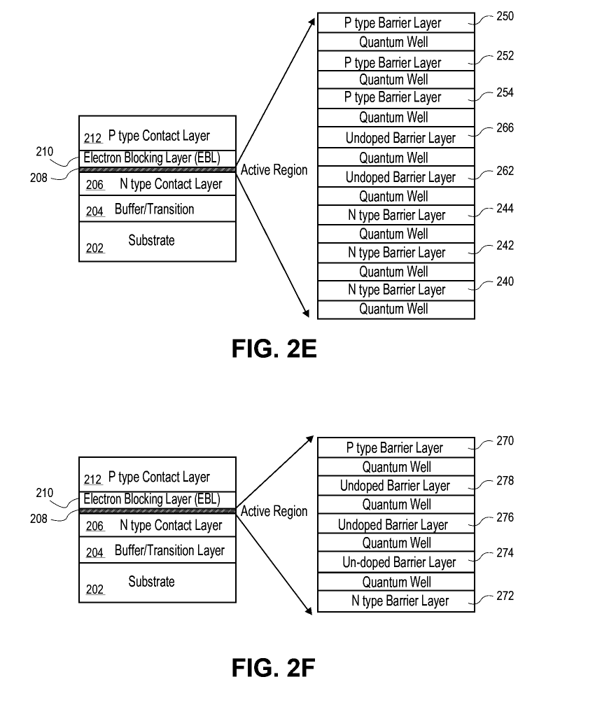

FIG. 2A illustrates a LED structure 200 in accordance with an embodiment of the present invention. LED structure 200 includes a bulk substrate 202. Bulk substrate may be any suitable substrate, such as but not limited to a sapphire (Al₂O₃) substrate, a silicon carbide (SiC) substrate, a silicon (Si) substrate, a zinc oxide (ZnO) substrate, a magnesium oxide (MgO) substrate, a gallium nitride (GaN) substrate, a lithium aluminum oxide (LiAlO₂) substrate and a lithium gallium oxide (LiGaO₂) substrate. Additionally substrate 202 may be a planar substrate or have patterned features therein. A buffer or transition layer 204 may be formed on the substrate 202. Buffer/transition layer 204 provides a buffer or transition between the substrate 202 and the subsequently formed device layers of the LED structure.

Next, an n type contact layer 206 is formed on the buffer/transition layer. N type contact layer 206 can be any n type doped III-V semiconductor film, such as but not limited to gallium nitride (GaN), gallium arsenide (GaAs), gallium phosphide (GaP), gallium arsenide phosphide (GaAsP), aluminum gallium indium phosphide (AlGaInP), indium gallium nitride (InGaN), and aluminum gallium indium phosphide (AlGaInP). In embodiments of the present invention, n type contact layer 206 can be single crystalline or polycrystalline. In a specific embodiment of the present invention, n type contact layer 206 is single crystalline. N type contact layer 206 is generally doped with silicon (Si) to a conductivity level of between 1×10¹⁸ to 5×10¹⁹ atoms/cm³. Additionally, n type contact layer 206 can be formed to a thickness between 4-10 microns.

An active region 208 is formed on n type contact layer 206. In an embodiment of the present invention, active region 208 comprises a single or multiple quantum wells. In an embodiment of the present invention, active region 208 includes a first quantum well 220 and a second quantum well 222 and a first barrier layer 224 and a second barrier layer 226. First quantum well 220 is formed on n type contact layer 206, first barrier layer 224 is formed on the first quantum well 220, second quantum well 222 is formed on first barrier layer 224, and second barrier layer 226 is formed on second quantum well 222. Quantum wells 220 and 222 and barriers 224 and 226 may be formed from any suitable III-V semiconductor material, such as but not limited to gallium nitride (GaN), gallium arsenide (GaAs), gallium phosphide (GaP), gallium arsenide phosphide (GaAsP), aluminum gallium indium phosphide (AlGaInP), indium gallium nitride (InGaN), and aluminum gallium indium phosphide (AlGaInP). In embodiments of the present invention, quantum wells 220 and 222 and barrier 224 and 226 can be single crystalline or polycrystalline. In a specific embodiment of the present invention, quantum wells 220 and 222 and barrier 224 and 226 are single crystalline. Quantum well 220 and 222 are formed from a III-V semiconductor material having a band gap which is less than the band gap of a III-V semiconductor material used to form the barriers 224 and 226 so that the barrier layers can confine the carriers within the well. The semiconductor materials of barrier layers 224 and 226 should have a band gap of at least 0.1 electron volts and preferably at least 0.2 volts greater than the band gap of the semiconductor used to form wells 220 and 222. Additionally, it is to be appreciated that typically all of the barrier layers 224 and 226 of the quantum well are formed of same semiconductor material and all of the wells 220 and 222 of the quantum wells are formed of the same semiconductor material. Generally, the type of semiconductor material chosen for the wells determines the frequency of the radiation emitted from the LED.

In an embodiment of the present invention, at least one of the barriers 224 and 226 is doped to a p type conductivity level. Barrier 224 or 226 can be doped to a p type conductivity utilizing any element having at least two valence electrons, such as but not limited to magnesium (Mg), cobalt (Co) and zinc (Zn). In a specific embodiment, the barrier layer is doped with magnesium. In an embodiment of the present invention, at least one of the barrier layers 224 and 226 is doped to a p type conductivity level of between 1×10¹⁷ to 1×10¹⁹ atoms/cm². The doping level and location of the p type barrier layer are chosen such that the location of the P-N junction is positioned within the active region so that the dominant recombination occurs within the active region 208.

In an embodiment of the present invention, LED structure 200 includes an electron blocking layer (EBL) 210 formed on active region 208. Electron blocking layer 210 is formed directly on the first barrier layer 224 of active region 208. Electron blocking layer 210 can be formed from any suitable III-V compound semiconductor, such as but not limited to gallium nitride (GaN), gallium arsenide (GaAs), gallium phosphide (GaP), gallium arsenide phosphide (GaAsP), aluminum gallium indium phosphide (AlGaInP), indium gallium nitride (InGaN), and aluminum gallium indium phosphide (AlGaInP). In embodiments of the present invention, electron blocking layer 210 can be single crystalline or polycrystalline. In a specific embodiment of the present invention, electron blocking layer 210 is single crystalline. The electron blocking layer 210 is provided to help confine the radiative recombination within the active region. Electron blocking layer 210 has a p type doping of between 1×10¹⁸ and 1×10²° atoms/cm³ and is formed to a thickness of about 100-500 Å. The band gap of electron blocking layer 210 is higher than the bandgap of the quantum wells and barrier layers.

Finally, a p type contact layer 212 is formed on the electron blocking layer 210. P type contact layer can be any suitable III-V semiconductor, such as but not limited to gallium nitride (GaN), gallium arsenide (GaAs), gallium phosphide (GaP), gallium arsenide phosphide (GaAsP), aluminum gallium indium phosphide (AlGaInP), indium gallium nitride (InGaN), and aluminum gallium indium phosphide (AlGaInP). In embodiments of the present invention, p type contact layer 212 can be single crystalline film or polycrystalline. In a specific embodiment of the present invention, p type contact layer 212 is single crystalline. P type contact layers can be doped to a p type conductivity level between 1×10¹⁹ to 1×10²¹ atoms/cm³ and can be formed to a thickness of approximately 100-500 nm.

In an embodiment of the present invention, the active device region 208 includes multiple barrier layers and quantum wells to fabricate a light emitting diode having multiple quantum wells (MQWs). In an embodiment of the present invention, active region 208 includes between 10 to 20 stacks of barrier layers and wells, wherein each stack includes a quantum well layer between 1-5 nm thick and a barrier layer between 1-30 nm thick. In an embodiment of the present invention, at least one of the barrier layers is doped to a p-type conductivity. In an embodiment of the present invention, each of the barrier layers are doped to a p-type conductivity. In yet another embodiment of the present invention, only the barrier layer in contact with the electron blocking layer (EBL) 210 is doped to a p type conductivity level. As set forth above, the barrier layer or barrier layers are lightly doped to a p type conductivity level of between 1×10¹⁷ to 1×10¹⁹ atoms/cm³.

FIG. 2B illustrates a specific embodiment of the present invention, wherein the substrate 202 is a (0001) sapphire substrate. The buffer/transition layer 204 is an undoped gallium nitride (GaN) layer. The n type contact layer 206 is a silicon doped gallium nitride (Si—GaN) layer. As illustrated in FIG. 2B, the active region 208 is made up of a plurality of magnesium doped gallium nitride (Mg—GaN) barrier layers 224/226 and a plurality of indium gallium nitride (InGaN) quantum well layers 220/222. The electron blocking layer 210 is a magnesium doped aluminum gallium nitride (Mg—AlGaN) layer. The p type contact layer 212 is a magnesium doped gallium nitride (Mg—GaN) layer.

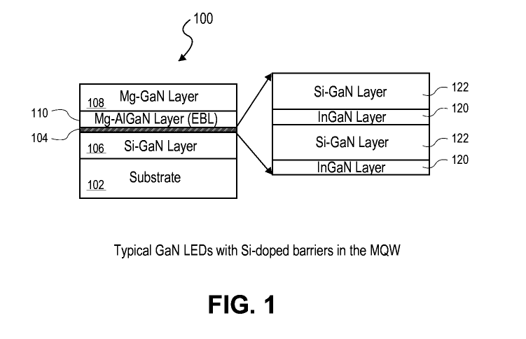

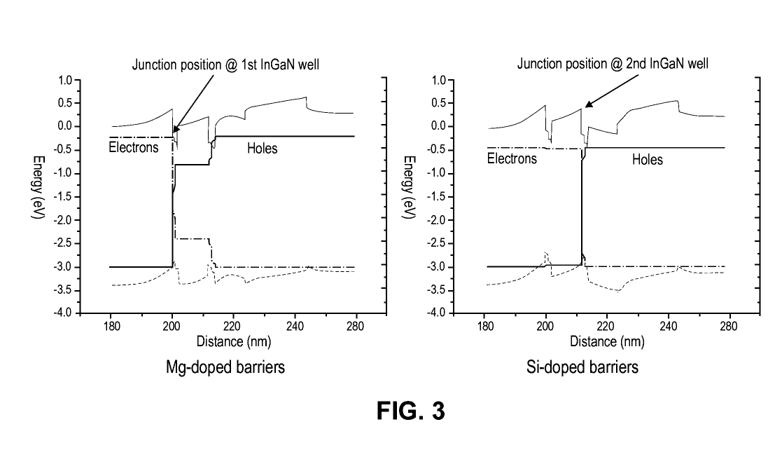

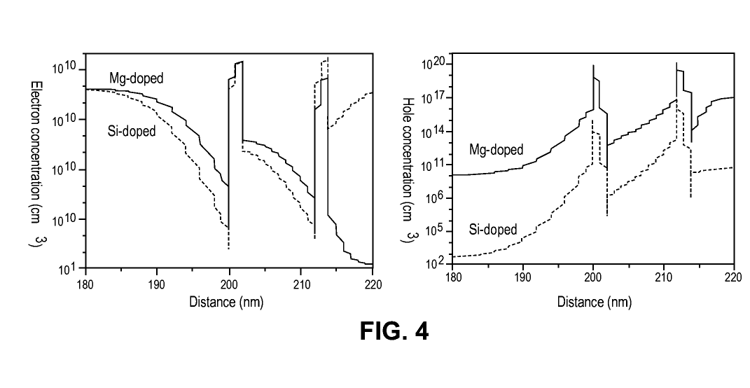

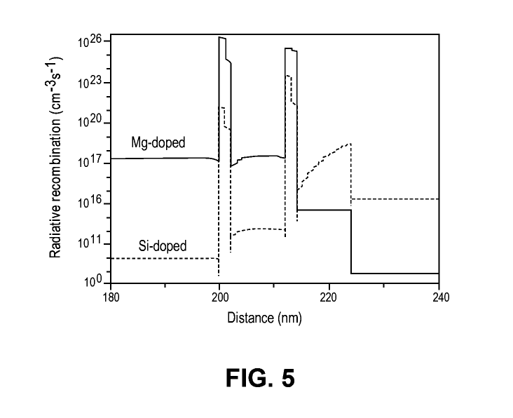

The p type doping in the active region shifts the P-N junction position towards the active region as shown in FIG. 3. With silicon doped barrier layers, such as the device shown in FIG. 1, the P-N junction position is located in the last indium gallium nitride (InGaN) well, while with magnesium doped barrier layers in the MQWs, the P-N junction position is shifted to the first indium gallium nitride (InGaN) well. FIG. 4 shows the difference of carrier concentration between the MQWs with magnesium doped barriers and that with silicon doped barriers. The hole concentration for the MQWs with magnesium doped barrier is significantly enhanced compared with that with silicon doped barriers. The radiative recombination is also considerably increased as a result of the high hole concentration in the active region with magnesium doped barriers as shown in FIG. 5.

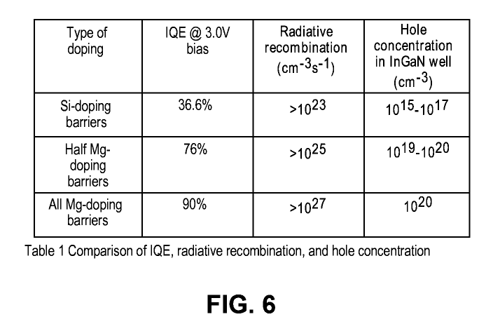

FIG. 6 illustrates the increase in the internal quantum efficiency (IQE) by doping the barriers with magnesium. Theoretically, the IQE can reach 90%. Although FIG. 6 indicates that the best IQE is obtained by magnesium doping in all gallium nitride barrier layer in the active region, additional factors, such as recombination rates, wavelength ranges of emitted light are also important to LED manufacturing. These factors can affect yield, brightness, color, etc. Accordingly, in practice, other embodiments may have advantages.

For example, in an embodiment of the present invention, as illustrated in FIG. 2C, not only are the barrier layers 224 and 226 doped to a p type conductivity level, but one or more of the quantum well layers 228 and 230 are also doped to a p type conductivity level. In an embodiment of the present invention, one or more of the quantum wells 228 and 230 are doped to a p type conductivity level between 1×10¹⁸-1×10¹⁹ atoms/cm³ with, for example, magnesium.

In another embodiment of the present invention, as illustrated in FIG. 2D, one or more of the barrier layers nearest the n type contact layer 206 are doped to an n type conductivity level while one or more of the barrier layers nearest the electron blocking layer (EBL) 210 and the p type contact layer 212 are doped to a p type conductivity level. The n type barrier layers can be doped with an n type dopant, such as but not limited to Si to a concentration between 1×10¹⁷-1×10¹⁹ atoms/cm³. Such a doping profile would concentrate most of the recombination in the middle of the active region. In another embodiment of the present invention, the barrier layers nearest the n type contact layers are doped to an n type conductivity in a graded fashion whereby the barrier layers nearest the n type contact are doped to a higher n type conductivity level than the n type barriers towards the center of the active region 208 while the barrier layers nearest the electron (EBL) barrier layer 210 are doped to a p type conductivity level in a graded fashion whereby the barrier layers nearest the EBL layer 210 have a higher p type conductivity level than the barrier layers towards the center of the active region 208. For example, as illustrated in FIG. 2D, barrier layer 240 is doped to an n type conductivity level N₁, such as 1×10¹⁸ atoms/cm³ which is greater than the n type conductivity level N₂, such as 5×10¹⁷ atoms/cm³ of barrier layer 242 which in turn is greater than the n type conductivity level N_{3,} such as 1×10¹⁷ atoms/cm³ of barrier layer 246. In a similar manner, barrier layer 250 closest to the EBL layer 210 is doped to a p type conductivity level P₁, such as 1×10¹⁹ atoms/cm³ which is greater than the p type conductivity level P₂, such as 5×10¹⁸ atoms/cm³ of the next adjacent barrier layer 252 which in turn is greater than the p type conductivity level P₃, such as 1×10¹⁸ atoms/cm³ of the next adjacent barrier layer 254.

FIG. 2E illustrates yet another embodiment of the present invention, which is similar to the above described embodiments except that one or more of the middle barrier layers is undoped. For example, one or more of the barrier layers 240, 242 and 244 adjacent to the n type contact are doped to an n type conductivity in a uniform or graded fashion, one or more of the barrier layers 250, 252 and 254 adjacent to the p type contact region are doped in an uniform or graded manner to a p type conductivity level and one or more of the barrier layers 206 and 262 located between the p type conductivity barrier layers and the n type conductivity layers are undoped.

In yet another embodiment of the present invention, as illustrated in FIG. 2F, only the barrier layers which share an interface with the electron blocking layer (EBL) 210 and the n type contact layer 206 are doped while the remaining barrier layers internal to the active region remain undoped. That is, for example, a p type barrier layer 270 is formed adjacent to electron blocking layer 210 and an n type barrier layer 272 is formed adjacent to n type contact layer 206. Barrier layers 274, 276 and 278 formed between the p type barrier 270 and n type barrier 272 are undoped.

The contacts layers, barrier layers, and quantum wells of the device of the present invention may be formed by any suitable technique, such as but not limited to hydride vapor phase epitaxial (HVPE), metal organic chemical vapor deposition (MOCVD) and plasma enhanced MOCVD. In an embodiment of the present invention, the layers of the LED device are fabricated in a cluster tool having a hydride vapor phase epitaxial (HVPE) deposition chamber and a metal organic chemical vapor deposition (MOCVD) chamber and/or a plasma enhanced MOCVD chamber. In an embodiment of the present invention, a second HVPE chamber is provided.

In an embodiment of the present invention, an indium gallium nitride (InGaN) well layer or layers are grown in one chamber by MOCVD or plasma enhanced MOCVD and a magnesium doped gallium nitride (Mg—GaN) barrier layer or layers are formed by another chamber, such as HVPE, to avoid indium (In) and magnesium (Mg) cross contamination in a single chamber. In an embodiment of the present invention, the magnesium doped gallium nitride (Mg—GaN) barrier layer is formed at a low temperature of between 600-900° C. which is compatible with the low temperature growth of indium gallium nitride (InGaN) quantum well layers in order to minimize cross interference between the magnesium and indium and thermal damage to the indium gallium nitride (InGaN) quantum wells.

An indium gallium nitride (InGaN) film may be formed by MOCVD by providing a metal organic source of indium, such as trimethylindium (TMIn) and an organic source of gallium, such as trimethylgallium (TMGa) into a chamber along with a nitrogen source, such as ammonia (NH₃) in a chamber containing a substrate. A carrier gas, such as N₂ may be utilized. The substrate may be heated to a growth temperature between 700-850° C. which causes the source gases to react and form an indium gallium nitride (InGaN) film on the substrate. The chamber can be maintained at a pressure between 100 torr to atmospheric pressure while depositing the indium gallium nitride (InGaN) film. In an embodiment of the present invention, the indium gallium nitride film has an atomic formula of In₁Ga₁₋ₓN where 0.05≦x≦0.25. A 20-80% indium atomic ratio in the gas phase with respect to gallium will yield between 5-25% indium in the solid phase. A p-type indium gallium nitride (p-InGaN) quantum well can be formed by MOCVD by including a p-type precursor, such as but not limited to biscyclopentadienyl maganesium (Cp₂Mg).

A magnesium doped gallium nitride (Mg—GaN) layer can be formed by HVPE by providing a gallium containing precursor, such as gallium chloride (GaCl or GaCl₃), a magnesium containing precursor, such as magnesium chloride (MgCl) and a nitrogen containing precursor, such as ammonia (NH₃) into a chamber and reacting them together near the surface of the substrate to deposit a magnesium doped gallium nitride (Mg—GaN) film. In an embodiment of the present invention, the gallium containing precursor is formed by providing a source of gallium, and flowing over it a halide or halogen gas to form a gaseous gallium containing precursor. In an embodiment of the present invention, HCl is reacted with a liquid gallium source to form gaseous gallium chloride (GaCl). In another embodiment of the present invention, chlorine gas (Cl₂) is reacted with a liquid gallium to form GaCl and GaCl₃. Similarly, a magnesium (Mg) containing precursor can be formed by providing a magnesium source and flowing over it a halide or halogen gas to form a magnesium containing precursor. In an embodiment of the present invention, Cl₂ is reacted with magnesium (Mg) to form magnesium chloride (MgCl). In an embodiment of the present invention, the chamber is maintained at a pressure between 100 torr and 760 torr during deposition. In one embodiment, the chamber is maintained at a pressure of about 450 torr to about 760 torr while depositing the magnesium doped gallium nitride (Mg—GaN) film. In an embodiment of the present invention, the magnesium doped gallium nitride film is formed at a temperature less than 900° C. and ideally the temperature is between 600-900° C. An n-type GaN layer, such as silicon doped gallium nitride (Si—GaN) layer can be formed in a similar manner except that the magnesium precursor would be replaced with a silicon precursor from a silicon source.

In an embodiment of the present invention, one or more magnesium doped gallium nitride (Mg—GaN) barrier layers are formed by HVPE using a magnesium gallium (MgGa) eutectic alloy as the source. HCl or chlorine gas (Cl₂) is then reacted with the magnesium gallium (MgGa) eutectic alloy to form gaseous magnesium chloride (MgCl) and gallium chloride (GaCl or GaCl₃).

In an embodiment of the present invention, one or more indium gallium nitride (InGaN) quantum wells are formed by HVPE in the same chamber as used to form the magnesium doped gallium nitride (Mg—GaN) barrier layers. In an embodiment of the present invention, an indium gallium nitride (InGaN) quantum well is formed by HVPE in the same chamber as the barrier layer but with a separate indium gallium (InGa) eutectic alloy as the source. Alternatively, the indium gallium nitride (InGaN) quantum well can be formed in a separate HVPE chamber than the chamber used Mg to form the barrier layers to avoid indium (In) and magnesium (Mg) cross contamination in a single chamber.

In yet another embodiment of the invention, the magnesium doped gallium nitride (Mg—GaN) barrier layer can be grown by plasma assisted MOCVD with a lower growth temperature of between 600-900° C. The thin indium gallium nitride (InGaN) quantum well layer can be deposited in the same chamber or another chamber by MOCVD or HVPE. In an embodiment of the present invention, an indium gallium nitride (InGaN) layer is formed by HVPE by providing an indium gallium (InGa) alloy source and flowing over it a halide or halogen gas, such as HCl or Cl₂ to obtain gaseous GaCl and InCl.

In yet another embodiment of the present invention, the top p type contact layer 212 can be grown at a lower temperature by plasma assisted MOCVD or HVPE method as discussed above to avoid the thermal damage to the InGaN quantum wells lying beneath. Still further, in another embodiment of the present invention, a p type aluminum gallium nitride (p-AlGaN) alloy electron blocking layer 210 can be deposited by plasma assisted MOCVD or by HVPE at lower growth temperatures of less than or equal to 950° C. An Mg—AlGaN electron blocking layer can be formed by HVPE in a manner similar to a Mg—GaN layer except that an aluminum (Al) source is also provided. A Mg-AlGaN can be formed by MOCVD in a similar manner as a Mg—InGaN layer except that an aluminum containing precursor, such as trimethylaluminum (TMAl) would be used instead of an indium containing precursor. In an embodiment of the present invention, the Mg—AlGaN film has an atomic formula of Mg—AlₓGa₁₋ₓN where 0.1≦X≦0.5.

In an embodiment of the present invention, the structures described above can be formed in a cluster tool having one or multiple processing chambers, such as a MOCVD chamber, a plasma enhanced MOCVD chamber, and a HVPE chamber. In an embodiment of the present invention, the cluster tool can include any well known plasma enhanced MOCVD chamber. Additionally, in an embodiment of the present invention, the described MOCVD chamber can operate in a plasma enhanced manner by including plasma generating means in the MOCVD chamber, including a downstream plasma chamber to activate the precursor gases prior to feeding them into the deposition chamber, or including both plasma generating means in the MOCVD chamber and including a downstream plasma chamber. In embodiments of the present invention, the cluster tool can have various configurations, such as but not limited to having two MOCVD chambers and one HVPE chamber, having three MOCVD chambers and one HVPE chamber, and having one MOCVD chamber, one plasma enhanced MOCVD chamber, and one HVPE chamber. It is to be appreciated that a substrate can be transferred between the processing chambers of the cluster tool without breaking vacuum.

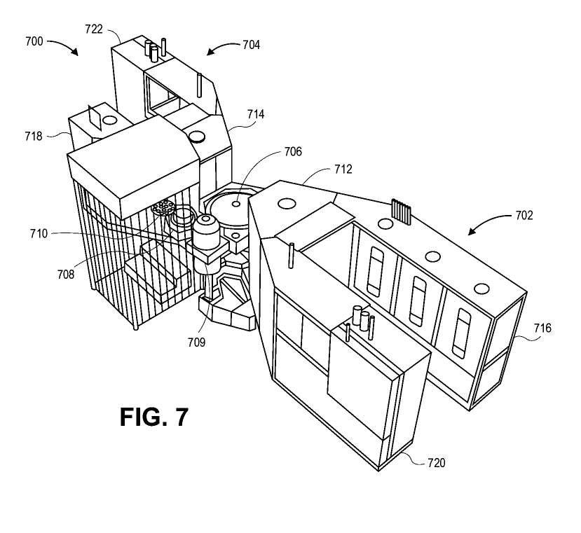

An example of a cluster tool which can be used to fabricate the LED structures in accordance with embodiments of the present invention is illustrated and described with respect to FIGS. 7-18.

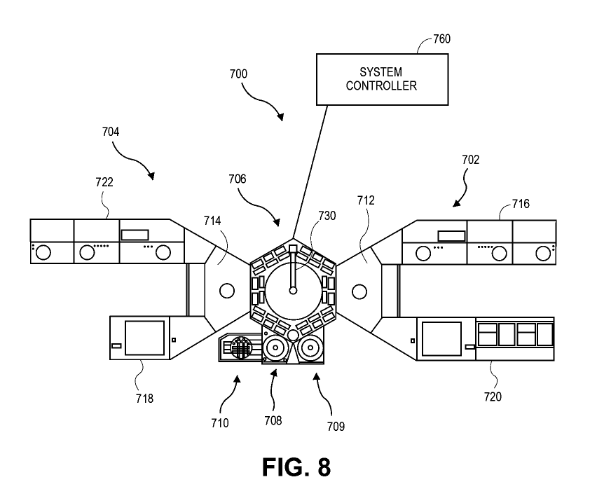

FIG. 7 is an isometric view of one embodiment of a processing system 700 that illustrates a number of aspects of the present invention that may be advantageously used. FIG. 8 illustrates a plan view of one embodiment of a processing system 700 illustrated in FIG. 7. With reference to FIG. 7 and FIG. 8, the processing system 700 comprises a transfer chamber 706 housing a substrate handler, a plurality of processing chambers coupled with the transfer chamber, such as a MOCVD chamber 702 and a HVPE chamber 704, a loadlock chamber 708 coupled with the transfer chamber 706, a batch loadlock chamber 709, for storing substrates, coupled with the transfer chamber 706, and a load station 710, for loading substrates, coupled with the loadlock chamber 708. The transfer chamber 706 comprises a robot assembly 730 operable to pick up and transfer substrates between the loadlock chamber 708, the batch loadlock chamber 709, the MOCVD chamber 702 and the HVPE chamber 704. The movement of the robot assembly 730 may be controlled by a motor drive system (not shown), which may include a servo or stepper motor.

Each processing chamber comprises a chamber body (such as element 712 for the MOCVD chamber 702 and element 714 for the HVPE chamber 704) forming a processing region where a substrate is placed to undergo processing, a chemical delivery module (such as element 716 for the MOCVD chamber 702 and element 718 for the HVPE chamber 704) from which gas precursors are delivered to the chamber body, and an electrical module (such as element 720 for the MOCVD chamber 702 and element 722 for the HVPE chamber 704) that includes the electrical system for each processing chamber of the processing system 700. The MOCVD chamber 702 is adapted to perform CVD processes in which metalorganic elements react with metal hydride elements to form thin layers of compound nitride semiconductor materials. The HVPE chamber 704 is adapted to perform HVPE processes in which gaseous metal halides are used to epitaxially grow thick layers of compound nitride semiconductor materials on heated substrates. In alternate embodiments, one or more additional chambers may 770 be coupled with the transfer chamber 706. These additional chambers may include, for example, anneal chambers, clean chambers for cleaning carrier plates, or substrate removal chambers. The structure of the processing system permits substrate transfers to occur in a defined ambient environment, including under vacuum, in the presence of a selected gas, under defined temperature conditions, and the like.

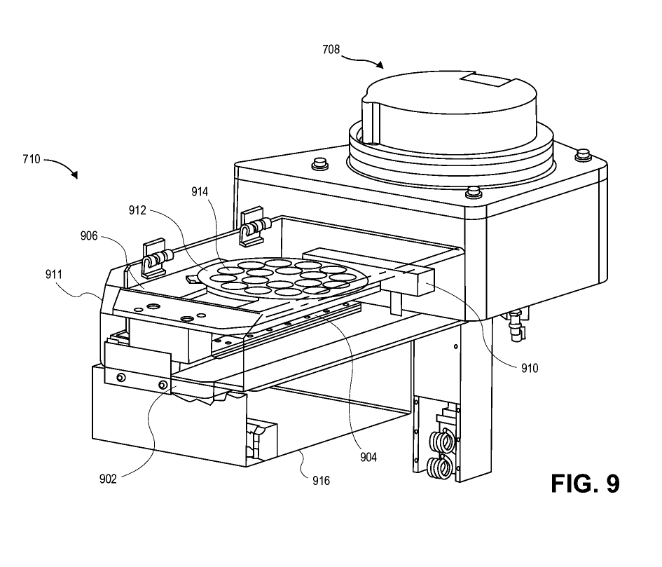

FIG. 9 is an isometric view illustrating a load station 710 and a loadlock chamber 708 according to an embodiment of the invention. The load station 710 is configured as an atmospheric interface to allow an operator to load a plurality of substrates for processing into the confined environment of the loadlock chamber 708, and unload a plurality of processed substrates from the loadlock chamber 708. The load station 710 comprises a frame 902, a rail track 904, a conveyor tray 906 adapted to slide along the rail track 904 to convey substrates into and out of the loadlock chamber 708 via a slit valve 910, and a lid 911. In one embodiment, the conveyor tray 906 may be moved along the rail track 904 manually by the operator. In another embodiment, the conveyor tray 906 may be driven mechanically by a motor. In yet another embodiment, the conveyor tray 906 is moved along the rail track 904 by a pneumatic actuator.

Substrates for processing may be grouped in batches and transported on the conveyor tray 906. For example, each batch of substrates 914 may be transported on a carrier plate 912 that can be placed on the conveyor tray 906. The lid 911 may be selectively opened and closed over the conveyor tray 906 for safety protection when the conveyor tray 906 is driven in movement. In operation, an operator opens the lid 911 to load the carrier plate 912 containing a batch of substrates on the conveyor tray 906. A storage shelf 916 may be provided for storing carrier plates containing substrates to be loaded. The lid 911 is closed, and the conveyor tray 906 is moved through the slit valve 910 into the loadlock chamber 708. The lid 911 may comprise a glass material, such as Plexiglas or a plastic material to facilitate monitoring of operations of the conveyor tray 906.

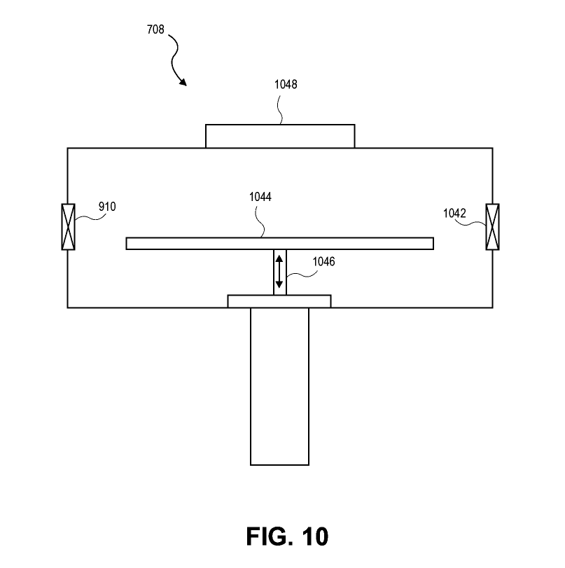

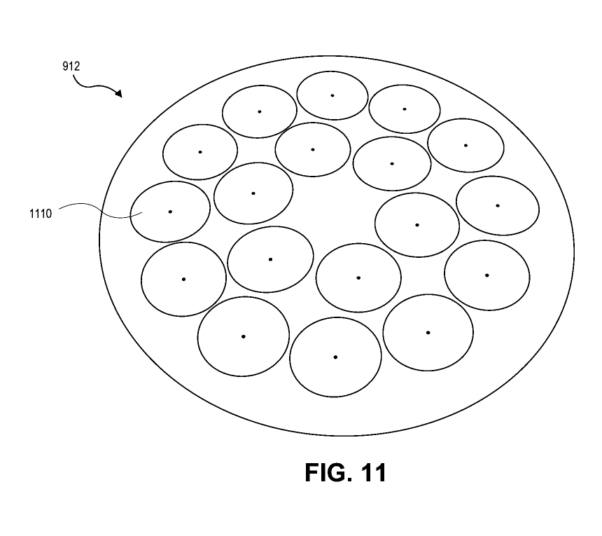

FIG. 10 is a schematic view of a loadlock chamber 708 according to an embodiment of the invention. The loadlock chamber 708 provides an interface between the atmospheric environment of the load station 710 and the controlled environment of the transfer chamber 706. Substrates are transferred between the loadlock chamber 708 and the load station 710 via the slit valve 910 and between the loadlock chamber 708 and the transfer chamber 706 via a slit valve 1042. The loadlock chamber 708 comprises a carrier support 1044 adapted to support incoming and outgoing carrier plates thereon. In one embodiment, the loadlock chamber 708 may comprise multiple carrier supports that are vertically stacked. To facilitate loading and unloading of a carrier plate, the carrier support 1044 may be coupled to a stem 1046 vertically movable to adjust the height of the carrier support 1044. The loadlock chamber 708 is coupled to a pressure control system (not shown) which pumps down and vents the loadlock chamber 708 to facilitate passing the substrate between the vacuum environment of the transfer chamber 706 and the substantially ambient (e.g., atmospheric) environment of the load station 710. In addition, the loadlock chamber 708 may also comprise features for temperature control, such as a degas module 1048 to heat substrates and remove moisture, or a cooling station (not shown) for cooling substrates during transfer. Once a carrier plate loaded with substrates has been conditioned in the loadlock chamber 708, the carrier plate may be transferred into the MOCVD chamber 702 or the HVPE chamber 704 for processing, or to the batch loadlock chamber 709 where multiple carrier plates are stored in standby for processing.

During operation, a carrier plate 912 containing a batch of substrates is loaded on the conveyor tray 906 in the load station 710. The conveyor tray 906 is then moved through the slit valve 910 into the loadlock chamber 708, placing the carrier plate 912 onto the carrier support 1044 inside the loadlock chamber 708, and the conveyor tray returns to the load station 710. While the carrier plate 912 is inside the loadlock chamber 708, the loadlock chamber 708 is pumped and purged with an inert gas, such as nitrogen, in order to remove any remaining oxygen, water vapor, and other types of contaminants. After the batch of substrates have been conditioned in the loadlock chamber, the robot assembly 730 may transfer the carrier plate 912 to either the MOCVD chamber 702 or, the HVPE chamber 704 to undergo deposition processes. In alternate embodiments, the carrier plate 912 may be transferred and stored in the batch loadlock chamber 709 on standby for processing in either the MOCVD chamber 702 or the HVPE chamber 704. After processing of the batch of substrates is complete, the carrier plate 912 may be transferred to the loadlock chamber 708, and then retrieved by the conveyor tray 906 and returned to the load station 710.

FIG. 11 is an isometric view of a carrier plate according to an embodiment of the invention. In one embodiment, the carrier plate 912 may include one or more circular recesses 1110 within which individual substrates may be disposed during processing. The size of each recess 1110 may be changed according to the size of the substrate to accommodate therein. In one embodiment, the carrier plate 912 may carry six or more substrates. In another embodiment, the carrier plate 912 carries eight substrates. In yet another embodiment, the carrier plate 912 carries 18 substrates. It is to be understood that more or less substrates may be carried on the carrier plate 912. Typical substrates may include sapphire, silicon carbide (SiC), silicon, or gallium nitride (GaN). It is to be understood that other types of substrates, such as glass substrates, may be processed. Substrate size may range from 50 mm-200 mm in diameter or larger. In one embodiment, each recess 1110 may be sized to receive a circular substrate having a diameter between about 2 inches and about 6 inches. The diameter of the carrier plate 912 may range from 200 mm-750 mm, for example, about 300 mm. The carrier plate 912 may be formed from a variety of materials, including SiC, SiC-coated graphite, or other materials resistant to the processing environment. Substrates of other sizes may also be processed within the processing system 700 according to the processes described herein.

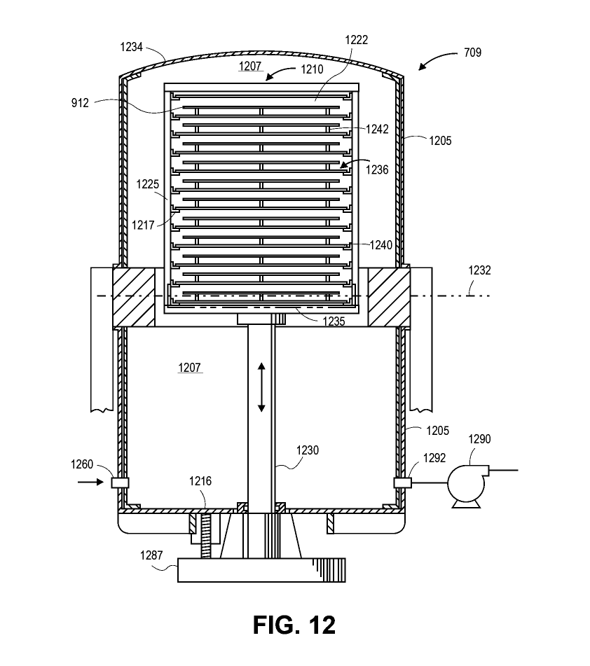

FIG. 12 is a schematic view of the batch loadlock chamber 709 according to an embodiment of the invention. The batch loadlock chamber 709 comprises a body 1205 and a lid 1234 and bottom 1216 disposed on the body 1205 and defining a cavity 1207 for storing a plurality of substrates placed on the carrier plates 912 therein. In one aspect, the body 1205 is formed of process resistant materials such as aluminum, steel, nickel, and the like, adapted to withstand process temperatures and is generally free of contaminates such as copper. The body 1205 may comprise a gas inlet 1260 extending into the cavity 1207 for connecting the batch loadlock chamber 709 to a process gas supply (not shown) for delivery of processing gases therethrough. In another aspect, a vacuum pump 1290 may be coupled to the cavity 1207 through a vacuum port 1292 to maintain a vacuum within the cavity 1207.

A storage cassette 1210 is moveably disposed within the cavity 1207 and is coupled with an upper end of a movable member 1230. The moveable member 1230 is comprised of process resistant materials such as aluminum, steel, nickel, and the like, adapted to withstand process temperatures and generally free of contaminates such as copper. The movable member 1230 enters the cavity 1207 through the bottom 1216. The movable member 1230 is slidably and sealably disposed through the bottom 1216 and is raised and lowered by the platform 1287. The platform 1287 supports a lower end of the movable member 1230 such that the movable member 1230 is vertically raised or lowered in conjunction with the raising or lowering of the platform 1287. The movable member 1230 vertically raises and lowers the storage cassette 1210 within the cavity 1207 to move the substrates carrier plates 912 across a substrate transfer plane 1232 extending through a window 1235. The substrate transfer plane 1232 is defined by the path along which substrates are moved into and out of the storage cassette 1210 by the robot assembly 730.

The storage cassette 1210 comprises a plurality of storage shelves 1236 supported by a frame 1225. Although in one aspect, FIG. 12 illustrates twelve storage shelves 1236 within storage cassette 1210, it is contemplated that any number of shelves may be used. Each storage shelf 1236 comprises a substrate support 1240 connected by brackets 1217 to the frame 1225. The brackets 1217 connect the edges of the substrate support 1240 to the frame 1225 and may be attached to both the frame 1225 and substrate support 1240 using adhesives such as pressure sensitive adhesives, ceramic bonding, glue, and the like, or fasteners such as screws, bolts, clips, and the like that are process resistant and are free of contaminates such as copper. The frame 1225 and brackets 1217 are comprised of process resistant materials such as ceramics, aluminum, steel, nickel, and the like that are process resistant and are generally free of contaminates such as copper. While the frame 1225 and brackets 1217 may be separate items, it is contemplated that the brackets 1217 may be integral to the frame 1225 to form support members for the substrate supports 1240.

The storage shelves 1236 are spaced vertically apart and parallel within the storage cassette 1210 to define a plurality of storage spaces 1222. Each substrate storage space 1222 is adapted to store at least one carrier plate 912 therein supported on a plurality of support pins 1242. The storage shelves 1236 above and below each carrier plate 912 establish the upper and lower boundary of the storage space 1222.

In another embodiment, substrate support 1240 is not present and the carrier plates 912 rest on brackets 1217.

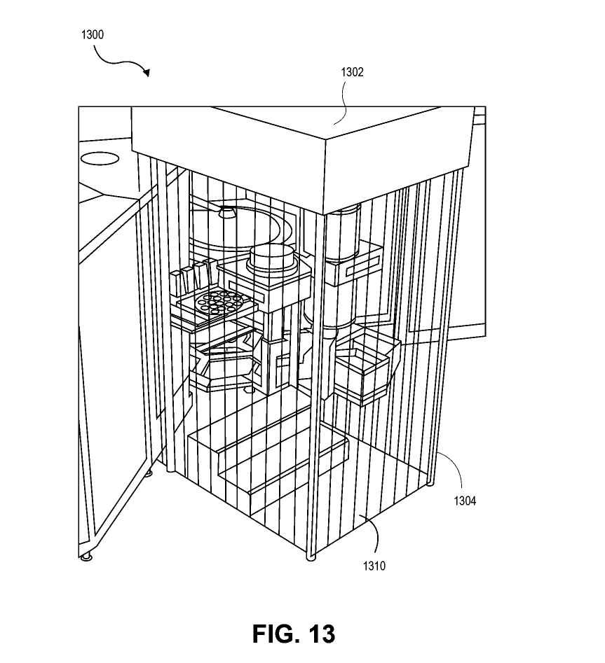

FIG. 13 is an isometric view of a work platform 1300 according to one embodiment of the invention. In one embodiment, the processing system 700 further comprises a work platform 1300 enclosing the load station 710. The work platform 1300 provides a particle free environment during loading and unloading of substrates into the load station 710. The work platform 1300 comprises a top portion 1302 supported by four posts 1304. A curtain 1310 separates the environment inside the work platform 1300 from the surrounding environment. In one embodiment, the curtain 1310 comprises a vinyl material. In one embodiment the work platform comprises an air filter, such as a High Efficiency Particulate Air Filter (“HEPA”) filter for filtering airborne particles from the ambient inside the work platform. In one embodiment, air pressure within the enclosed work platform 1300 is maintained at a slightly higher pressure than the atmosphere outside of the work platform 1300 thus causing air to flow out of the work platform 1300 rather than into the work platform 1300.

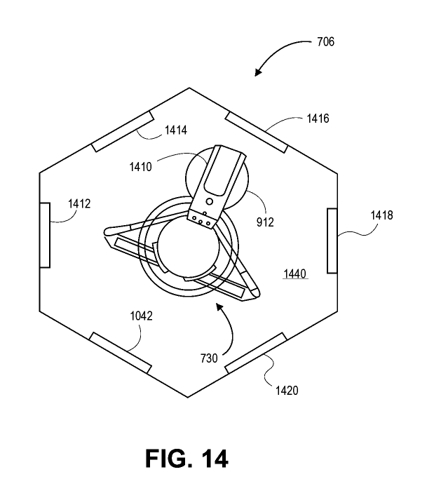

FIG. 14 is a plan view of a robot assembly 730 shown in the context of the transfer chamber 706. The internal region (e.g., transfer region 1440) of the transfer chamber 706 is typically maintained at a vacuum condition and provides an intermediate region in which to shuttle substrates from one chamber to another and/or to the loadlock chamber 708 and other chambers in communication with the cluster tool. The vacuum condition is typically achieved by use of one or more vacuum pumps (not shown), such as a conventional rough pump, Roots Blower, conventional turbo-pump, conventional cryo-pump, or combination thereof. Alternately, the internal region of the transfer chamber 706 may be an inert environment that is maintained at or near atmospheric pressure by continually delivering an inert gas to the internal region. Three such platforms are the Centura, the Endura and the Producer system all available from Applied Materials, Inc., of Santa Clara, Calif. The details of one such staged-vacuum substrate processing system are disclosed in U.S. Pat. No. 5,186,718, entitled “Staged-Vacuum Substrate Processing System and Method,” Tepman et al., issued on Feb. 16, 1993, which is incorporated herein by reference. The exact arrangement and combination of chambers may be altered for purposes of performing specific steps of a fabrication process.

The robot assembly 730 is centrally located within the transfer chamber 706 such that substrates can be transferred into and out of adjacent processing chambers, the loadlock chamber 708, and the batch loadlock chamber 709, and other chambers through slit valves 1042, 1412, 1414, 1416, 1418, and 1420 respectively. The valves enable communication between the processing chambers, the loadlock chamber 708, the batch loadlock chamber 709, and the transfer chamber 706 while also providing vacuum isolation of the environments within each of the chambers to enable a staged vacuum within the system. The robot assembly 730 may comprise a frog-leg mechanism. In certain embodiments, the robot assembly 730 may comprise any variety of known mechanical mechanisms for effecting linear extension into and out of the various process chambers. A blade 1410 is coupled with the robot assembly 730. The blade 1410 is configured to transfer the carrier plate 912 through the processing systems. In one embodiment, the processing system 700 comprises an automatic center finder (not shown). The automatic center finder allows for the precise location of the carrier plate 912 on the robot assembly 730 to be determined and provided to a controller. Knowing the exact center of the carrier plate 912 allows the computer to adjust for the variable position of each carrier plate 912 on the blade and precisely position each carrier plate 912 in the processing chambers.

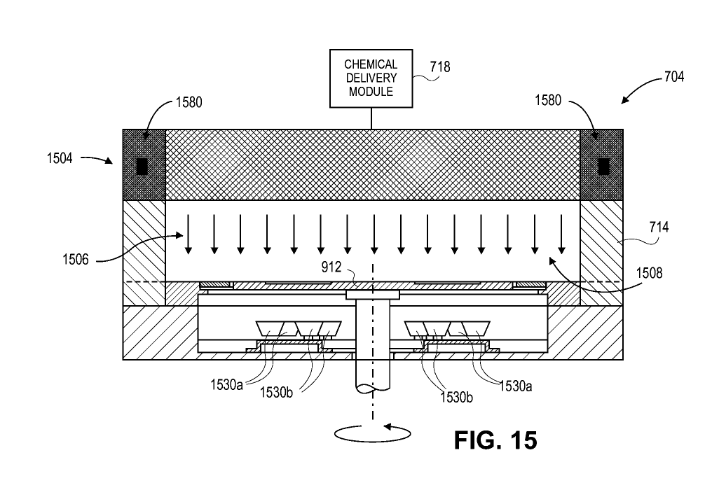

FIG. 15 is a schematic cross-sectional view of a HVPE chamber 704 according to an embodiment of the invention. The HVPE chamber 704 includes the chamber body 714 that encloses a processing volume 1508. A showerhead assembly 1504 is disposed at one end of the processing volume 1508, and the carrier plate 912 is disposed at the other end of the processing volume 1508. The showerhead assembly, as described above, may allow for more uniform deposition across a greater number of substrates or larger substrates than in traditional HVPE chambers, thereby reducing production costs. The showerhead may be coupled with a chemical delivery module 718. The carrier plate 912 may rotate about its central axis during processing. In one embodiment, the carrier plate 912 may be rotated at about 2 RPM to about 100 RPM. In another embodiment, the carrier plate 912 may be rotated at about 30 RPM. Rotating the carrier plate 912 aids in providing uniform exposure of the processing gases to each substrate.

A plurality of lamps 1530a, 1530b may be disposed below the carrier plate 912. For many applications, a typical lamp arrangement may comprise banks of lamps above (not shown) and below (as shown) the substrate. One embodiment may incorporate lamps from the sides. In certain embodiments, the lamps may be arranged in concentric circles. For example, the inner array of lamps 1530b may include eight lamps, and the outer array of lamps 1530a may include twelve lamps. In one embodiment of the invention, the lamps 1530a, 1530b are each individually powered. In another embodiment, arrays of lamps 1530a, 1530b may be positioned above or within showerhead assembly 1504. It is understood that other arrangements and other numbers of lamps are possible. The arrays of lamps 1530a, 1530b may be selectively powered to heat the inner and outer areas of the carrier plate 912. In one embodiment, the lamps 1530a, 1530b are collectively powered as inner and outer arrays in which the top and bottom arrays are either collectively powered or separately powered. In yet another embodiment, separate lamps or heating elements may be positioned over and/or under the source boat 1580. It is to be understood that the invention is not restricted to the use of arrays of lamps. Any suitable heating source may be utilized to ensure that the proper temperature is adequately applied to the processing chamber, substrates therein, and a metal source. For example, it is contemplated that a rapid thermal processing lamp system may be utilized such as is described in United States Patent Publication No. 2006/0018639, published Jan. 26, 2006, entitled PROCESSING MULTILAYER SEMICONDUCTORS WITH MULTIPLE HEAT SOURCES, which is incorporated by reference in its entirety.

In yet another embodiment, the source boat 1580 is remotely located with respect to the chamber body 714, as described in U.S. Provisional Patent Application Ser. No. 60/978,040, filed Oct. 5, 2007, titled METHOD FOR DEPOSITING GROUP III/V COMPOUNDS, which is incorporated by reference in its entirety.

One or more lamps 1530a, 1530b may be powered to heat the substrates as well as the source boat 1580. The lamps may heat the substrate to a temperature of about 900° C. to about 1200° C. In another embodiment, the lamps 1530a, 1530b maintain a metal source within the source boat 1580 at a temperature of about 350° C. to about 900° C. A thermocouple may be used to measure the metal source temperature during processing. The temperature measured by the thermocouple may be fed back to a controller that adjusts the heat provided from the heating lamps 1530a, 1530b so that the temperature of the metal source may be controlled or adjusted as necessary.

During the process according to one embodiment of the invention, precursor gases 1506 flow from the showerhead assembly 1504 towards the substrate surface. Reaction of the precursor gases 1506 at or near the substrate surface may deposit various metal nitride layers upon the substrate, including GaN, AN, and InN. Multiple metals may also be utilized for the deposition of “combination films” such as AlGaN and/or InGaN. The processing volume 1508 may be maintained at a pressure of about 760 torr down to about 100 torr. In one embodiment, the processing volume 1508 is maintained at a pressure of about 450 torr to about 760 torr. Exemplary embodiments of the showerhead assembly 1504 and other aspects of the HVPE chamber are described in U.S. patent application Ser. No. 11/767,520, filed Jun. 24, 2007, entitled HVPE TUBE SHOWERHEAD DESIGN, which is herein incorporated by reference in its entirety. Exemplary embodiments of the HVPE chamber 704 are described in U.S. patent application Ser. No. 61/172,630, filed Apr. 24, 2009, entitled HVPE CHAMBER HARDWARE, which is herein incorporated by reference in its entirety.

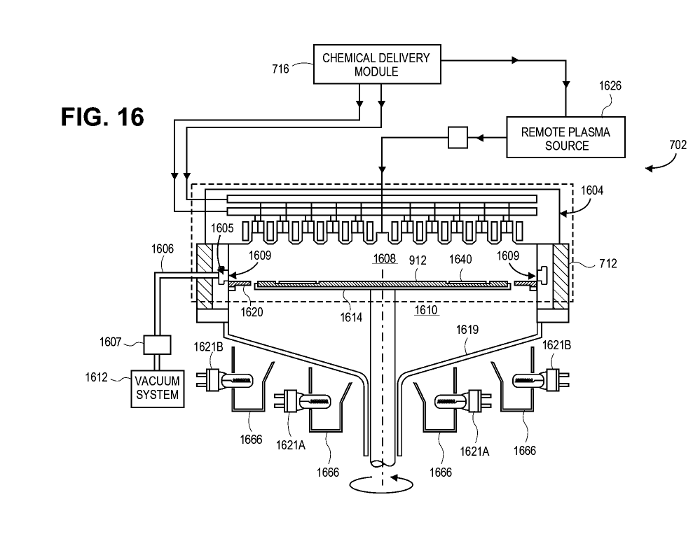

FIG. 16 is a schematic cross-sectional view of an MOCVD chamber according to an embodiment of the invention. The MOCVD chamber 702 comprises a chamber body 712, a chemical delivery module 716, a remote plasma source 1626, a substrate support 1614, and a vacuum system 1612. The chamber 702 includes a chamber body 712 that encloses a processing volume 1608. A showerhead assembly 1604 is disposed at one end of the processing volume 1608, and a carrier plate 912 is disposed at the other end of the processing volume 1608. The carrier plate 912 may be disposed on the substrate support 1614. Exemplary showerheads that may be adapted to practice the present invention are described in U.S. patent application Ser. No. 11/873,132, filed Oct. 16, 2007, entitled MULTI-GAS STRAIGHT CHANNEL SHOWERHEAD, U.S. patent application Ser. No. 11/873,141, filed Oct. 16, 2007, entitled MULTI-GAS SPIRAL CHANNEL SHOWERHEAD, and Ser. No. 11/873,170, filed Oct. 16, 2007, entitled MULTI-GAS CONCENTRIC INJECTION SHOWERHEAD, all of which are incorporated by reference in their entireties.

A lower dome 1619 is disposed at one end of a lower volume 1610, and the carrier plate 912 is disposed at the other end of the lower volume 1610. The carrier plate 912 is shown in process position, but may be moved to a lower position where, for example, the substrates 1640 may be loaded or unloaded. An exhaust ring 1620 may be disposed around the periphery of the carrier plate 912 to help prevent deposition from occurring in the lower volume 1610 and also help direct exhaust gases from the chamber 702 to exhaust ports 1609. The lower dome 1619 may be made of transparent material, such as high-purity quartz, to allow light to pass through for radiant heating of the substrates 1640. The radiant heating may be provided by a plurality of inner lamps 1621A and outer lamps 1621B disposed below the lower dome 1619 and reflectors 1666 may be used to help control the chamber 702 exposure to the radiant energy provided by inner and outer lamps 1621A, 1621B. Additional rings of lamps may also be used for finer temperature control of the substrates 1640.

A purge gas (e.g., nitrogen) may be delivered into the chamber 702 from the showerhead assembly 1604 and/or from inlet ports or tubes (not shown) disposed below the carrier plate 912 and near the bottom of the chamber body 712. The purge gas enters the lower volume 1610 of the chamber 702 and flows upwards past the carrier plate 912 and exhaust ring 1620 and into multiple exhaust ports 1609 which are disposed around an annular exhaust channel 1605. An exhaust conduit 1606 connects the annular exhaust channel 1605 to a vacuum system 1612 which includes a vacuum pump (not shown). The chamber 702 pressure may be controlled using a valve system 1607 which controls the rate at which the exhaust gases are drawn from the annular exhaust channel 1605. Other aspects of the MOCVD chamber are described in U.S. patent application Ser. No. 12/023,520, filed Jan. 31, 2008, (attorney docket no. 011977) entitled CVD APPARATUS, which is herein incorporated by reference in its entirety.

Various metrology devices, such as, for example, reflectance monitors, thermocouples, or other temperature devices may also be coupled with the chamber 702. The metrology devices may be used to measure various film properties, such as thickness, roughness, composition, temperature or other properties. These measurements may be used in an automated real-time feedback control loop to control process conditions such as deposition rate and the corresponding thickness. Other aspects of chamber metrology are described in U.S. Patent Application Ser. No. 61/025,252, filed Jan. 31, 2008, (attorney docket no. 011007) entitled CLOSED LOOP MOCVD DEPOSITION CONTROL, which is herein incorporated by reference in its entirety.

The chemical delivery modules 716, 718 supply chemicals to the MOCVD chamber 702 and HVPE chamber 704 respectively. Reactive and carrier gases are supplied from the chemical delivery system through supply lines into a gas mixing box where they are mixed together and delivered to respective showerheads 1604 and 1504. Generally supply lines for each of the gases include shut-off valves that can be used to automatically or manually shut-off the flow of the gas into its associated line, and mass flow controllers or other types of controllers that measure the flow of gas or liquid through the supply lines. Supply lines for each of the gases may also include concentration monitors for monitoring precursor concentrations and providing real time feedback, backpressure regulators may be included to control precursor gas concentrations, valve switching control may be used for quick and accurate valve switching capability, moisture sensors in the gas lines measure water levels and can provide feedback to the system software which in turn can provide warnings/alerts to operators. The gas lines may also be heated to prevent precursors and etchant gases from condensing in the supply lines. Depending upon the process used some of the sources may be liquid rather than gas. When liquid sources are used, the chemical delivery module includes a liquid injection system or other appropriate mechanism (e.g. a bubbler) to vaporize the liquid. Vapor from the liquids is then usually mixed with a carrier gas as would be understood by a person of skill in the art.

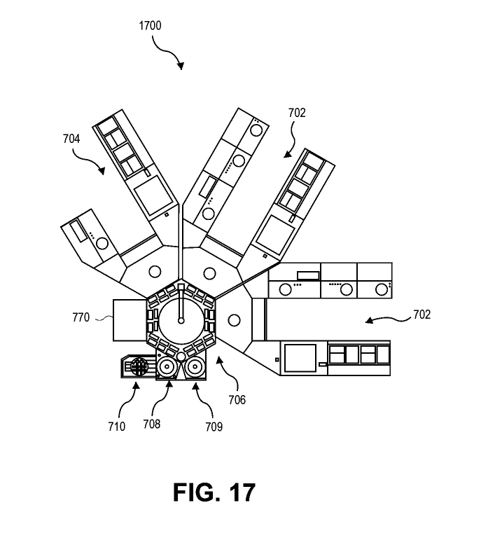

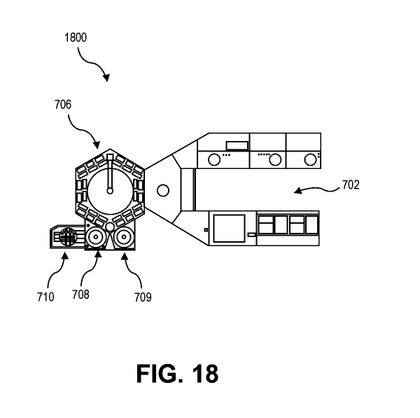

While the foregoing embodiments have been described in connection to a processing system that comprises one MOCVD chamber and one HVPE chamber, alternate embodiments may integrate one or more MOCVD and HVPE chambers in the processing system, as shown in FIGS. 17 and 18. FIG. 17 illustrates an embodiment of a processing system 1700 that comprises two MOCVD chambers 702 and one HVPE chamber 704 coupled to the transfer chamber 706. In the processing system 1700, the robot blade is operable to respectively transfer a carrier plate into each of the MOCVD chambers 702 and HVPE chamber 704. Multiple batches of substrates loaded on separate carrier plates thus can be processed in parallel in each of the MOCVD chambers 702 and HVPE chamber 704.

FIG. 18 illustrates a simpler embodiment of a processing system 1800 that comprises a single MOCVD chamber 702. In the processing system 1800, the robot blade transfers a carrier plate loaded with substrates into the single MOCVD chamber 702 to undergo deposition. After all the deposition steps have been completed, the carrier plate is transferred from the MOCVD chamber 702 back to the loadlock chamber 708, and then released toward the load station 710.

A system controller 760 controls activities and operating parameters of the processing system 700. The system controller 760 includes a computer processor and a computer-readable memory coupled to the processor. The processor executes system control software, such as a computer program stored in memory. Aspects of the processing system and methods of use are further described in U.S. patent application Ser. No. 11/404,516, filed Apr. 14, 2006, entitled EPITAXIAL GROWTH OF COMPOUND NITRIDE STRUCTURES, which is hereby incorporated by reference in its entirety.

The system controller 760 and related control software prioritize tasks and substrate movements based on inputs from the user and various sensors distributed throughout the processing system 700. The system controller 760 and related control software allow for automation of the scheduling/handling functions of the processing system 700 to provide the most efficient use of resources without the need for human intervention. In one aspect, the system controller 760 and related control software adjust the substrate transfer sequence through the processing system 700 based on a calculated optimized throughput or to work around processing chambers that have become inoperable. In another aspect, the scheduling/handling functions pertain to the sequence of processes required for the fabrication of compound nitride structures on substrates, especially for processes that occur in one or more processing chambers. In yet another aspect, the scheduling/handling functions pertain to efficient and automated processing of multiple batches of substrates, whereby a batch of substrates is contained on a carrier. In yet another aspect, the scheduling/handling functions pertain to periodic in-situ cleaning of processing chambers or other maintenance related processes. In yet another aspect, the scheduling/handling functions pertain to temporary storage of substrates in the batch loadlock chamber. In yet another aspect the scheduling/handling functions pertain to transfer of substrates to or from the load station based on operator inputs.

The following example is provided to illustrate how the general process described in connection with processing system 700 may be used for the fabrication of compound nitride structures. The example refers to a LED structure, with its fabrication being performed using a processing system 700 having at least two processing chambers, such as MOCVD chamber 702 and HVPE chamber 704. The cleaning and deposition of the initial GaN layers is performed in the HVPE chamber 704, with growth of the remaining InGaN, AlGaN, and GaN contact layers being performed in the MOCVD system 702.

The process begins with a carrier plate containing multiple substrates being transferred into the HVPE chamber 704. The HVPE chamber 704 is configured to provide rapid deposition of GaN. A pretreatment process and/or buffer layer is grown over the substrate in the HVPE chamber 704 using HVPE precursor gases. This is followed by growth of a thick n-GaN layer, which in this example is performed using HVPE precursor gases. In another embodiment the pretreatment process and/or buffer layer is grown in the MOCVD chamber and the thick n-GaN layer is grown in the HVPE chamber.

After deposition of the n-GaN layer, the substrate is transferred out of the HVPE chamber 704 and into the MOCVD chamber 702, with the transfer taking place in a high-purity N₂ atmosphere via the transfer chamber 706. The MOCVD chamber 702 is adapted to provide highly uniform deposition, perhaps at the expense of overall deposition rate. In the MOCVD chamber 702, the InGaN multi-quantum-well active layer is grown after deposition of a transition GaN layer. This is followed by deposition of the p-AlGaN layer and p-GaN layer. In another embodiment the p-GaN layer is grown in the HVPE chamber.

The completed structure is then transferred out of the MOCVD chamber 702 so that the MOCVD chamber 702 is ready to receive an additional carrier plate containing partially processed substrates from the HVPE chamber 704 or from a different processing chamber. The completed structure may either be transferred to the batch loadlock chamber 709 for storage or may exit the processing system 700 via the loadlock chamber 708 and the load station 710.

Before receiving additional substrates the HVPE chamber and/or MOCVD chamber may be cleaned via an in-situ clean process. The cleaning process may comprise etchant gases which thermally etch deposition from chamber walls and surfaces. In another embodiment, the cleaning process comprises a plasma generated by a remote plasma generator. Exemplary cleaning processes are described in U.S. patent application Ser. No. 11/404,516, filed on Apr. 14, 2006, and U.S. patent application Ser. No. 11/767,520, filed on Jun. 24, 2007, titled HVPE SHOWERHEAD DESIGN, both of which are incorporated by reference in their entireties.

An improved system and method for fabricating compound nitride semiconductor devices has been provided. In conventional manufacturing of compound nitride semiconductor structures, multiple epitaxial deposition steps are performed in a single process reactor, with the substrate not leaving the process reactor until all of the steps have been completed resulting in a long processing time, usually on the order of 4-6 hours. Conventional systems also require that the reactor be manually opened in order to remove and insert additional substrates. After opening the reactor, in many cases, an additional 4 hours of pumping, purging, cleaning, opening, and loading must be performed resulting in a total run time of about 8-10 hours per substrate. The conventional single reactor approach also prevents optimization of the reactor for individual process steps.

The improved system provides for simultaneously processing substrates using a multi-chamber processing system that has an increased system throughput, increased system reliability, and increased substrate to substrate uniformity. The multi-chamber processing system expands the available process window for different compound structures by performing epitaxial growth of different compounds in different processing having structures adapted to enhance those specific procedures. Since the transfer of substrates is automated and performed in a controlled environment, this eliminates the need for opening the reactor and performing a long pumping, purging, cleaning, opening, and loading process.

Thus, a light emitting diode with enhanced internal quantum efficiency and its method of fabrication have been described.

Also disclosed herein are sources for and methods of doping group III-nitrides by hydride vapor phase epitaxy using group III-metal eutectics. In an embodiment, a source is provided for HVPE deposition of a p-type group III-nitride epitaxial film. The source includes a liquid phase mechanical (eutectic) mixture of a group III species and a species such as, but not limited to, a group II species, a group I species, or a species not in group I or II but having a valence charge of one or two. In an embodiment, a method is provided for performing HVPE deposition of a p-type group III-nitride epitaxial film. The method includes using a liquid phase mechanical (eutectic) mixture of a group III species and a species such as, but not limited to, a group II species, a group I species, or a species not in group I or II but having a valence charge of one or two. In an embodiment, a source is provided for HVPE deposition of an n-type group III-nitride epitaxial film. The source includes a liquid phase mechanical (eutectic) mixture of a group III species and a group IV or VI species. In an embodiment, a method is provided for performing HVPE deposition of an n-type group III-nitride epitaxial film. The method includes using a liquid phase mechanical (eutectic) mixture of a group III species and a group IV or VI species. In an embodiment, the group III species referred to herein is gallium.

In accordance with an embodiment of the present invention, a eutectic mixture is used in at least one of, or a combination of, processes including: (a) hydride vapor phase epitaxy (HVPE), (b) the formation of gallium nitride or other group III nitrides, (c) doping of III-V material films or other semiconductor films, (d) the fabrication of light-emitting diodes (LEDs), (e) the fabrication of laser diodes (LDs), and (f) the fabrication of electronic devices such as field emission transistors. In an embodiment, group III-nitride film doping is performed by HVPE with a gallium-metal eutectic source, where the metal could be any metal of group II or group I for p-type and group IV for n-type doping, respectively. In an embodiment, group II or group IV doping is performed for a cation site in a III-V material, while group VI doping is used for n-type doping of an anion site in a III-V material. In another embodiment, group II doping is performed for a cation site in a III-V material, while or group IV or group VI doping is used for n-type doping of an anion site in a III-V material In accordance with an embodiment of the present invention, an advantage of using HVPE for p-type doping comes from the ability to exclude H₂ as a carrier gas, essentially eliminating Mg-H complex formation. This advantage may aid in overcoming a major obstacle for active magnesium formation, which typically requires additional, potentially harmful, annealing post deposition.

Often, group III-V materials, such as group III-nitrides are doped to enhance the electrical or photonic properties of these materials. However, such doping may not be straightforward, depending on the technique used to fabricate and dope the III-V material. For example, in accordance with an embodiment of the present invention, p-type doping of group III-nitride materials may be difficult. In one embodiment, metal-organic chemical vapor deposition (MO-CVD) precursors used for p-type doping can inadvertently carry carbon atoms into the III-V material. Carbon is an n-type dopant for group III-nitrides, thus detracting from the attempt to p-type dope the film. In another embodiment, hydride vapor phase epitaxy (HVPE) is used to eliminate the contamination with carbon. However, finding a p-type source, e.g. a source of magnesium or beryllium atoms, compatible with HVPE may be challenging because the p-type dopant is required to substitute the group III element in a group III-nitride epitaxial film. Thus, in accordance with an embodiment of the present invention, a mechanical mixture, or eutectic, including a p-type dopant is used for HVPE deposition of a group III-nitride film. For example, in one embodiment, a liquid phase mechanical mixture of gallium with beryllium or with magnesium (the beryllium or magnesium acting as the p-type dopant), or eutectic, is used as a source in the HVPE deposition of p-type gallium nitride (GaN).

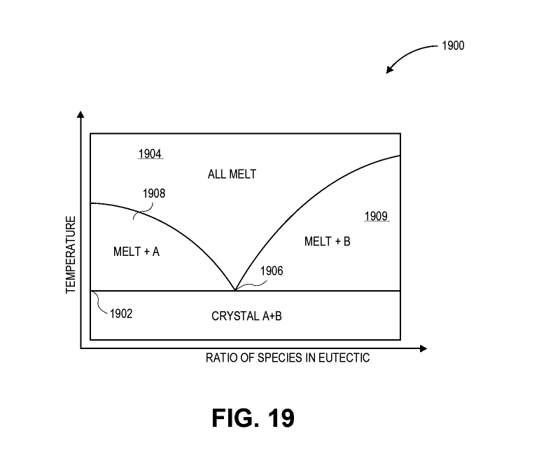

Mixtures of elements in a eutectic may be varied to very the temperature at which the eutectic melts and, thus, may affect the temperature at which the eutectic may be used as a liquid phase precursor or source for HVPE processes. FIG. 19 illustrates a plot 1900 of temperature as a function of a ratio of species A and B in a eutectic, in accordance with an embodiment of the present invention.

Referring to FIG. 19, a mixture of pure species A and B is solid (e.g., crystalline) below a particular temperature value 1902 and is liquid (e.g., all melted) in a region 1904 that sits above the particular temperature value 1902. However, there is only one specific mixture A +B for which all of the mixture is melted at the particular temperature value 1902. That one specific mixture is found at the eutectic point 1906. It is to be understood that other references to eutectic herein refer to mixture and temperature combinations that fall in the region 1904. Only if the term “eutectic point” is used will a term including “eutectic” be taken to mean the single point 1906. Referring again to FIG. 19, region 1908 is a temperature and mixture ratio combination for which all of pure species B and only a portion of pure species A are melted. This region includes solid portions of A Likewise, region 1909 is a temperature and mixture ratio combination for which all of pure species A and only a portion of pure species B are melted. This region includes solid portions of B. Thus, for combinations of mixture ratios and temperatures in region 1904, a mechanical mixture of A and B is in the liquid form. In accordance with an embodiment of the present invention, such a mixture can be used as a source of species A and B in an HVPE deposition process. In a specific embodiment, the extent to which a temperature is selected above the particular temperature value 1906 for the given A/B mechanical mixture, the type of halide formed can be varied when a halide gas is flowed over the mechanical mixture. In a particular embodiment, a ratio of beryllium:gallium of approximately 1:49 is a liquid mechanical mixture at and above approximately 800 degrees Celsius. In that embodiment, the liquid mechanical mixture having the ratio of beryllium:gallium of approximately 1:49 is used as a source for HVPE deposition at or slightly above 800 degrees Celsius.

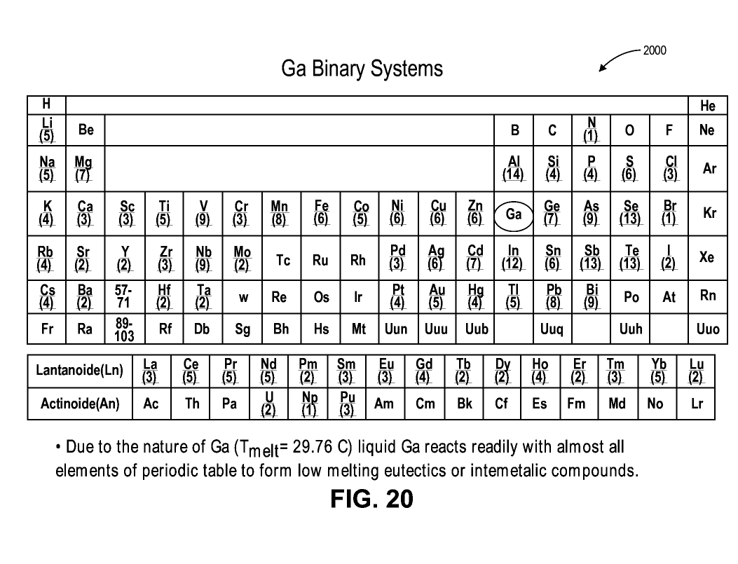

In accordance with an embodiment of the present invention, an advantage possibly unique to gallium is exploited, where gallium is a common source metal used in HVPE process formation of group III-nitride materials. In an embodiment, gallium is used to form a eutectic mixture for an HVPE source. Gallium may be used to form a eutectic with almost every element of periodic table, with very rare exceptions. For example, FIG. 20 illustrates, in a periodic table format 2000, a variety of gallium binary systems, in accordance with an embodiment of the present invention. In one embodiment, by forming such eutectics, a variety of dopants available for HVPE processes is broadened significantly. In an embodiment, the overall cost of an HVPE process is lowered by using a eutectic as a metal source, as compared with using metal-organic compound precursors. In one embodiment, the specific composition of a eutectic mixture for HVPE is selected by consulting temperature-composition phase diagrams of binary compounds.

As described above, in accordance with an embodiment of the present invention, a liquid phase mechanical mixture of a group III species (such as boron, aluminum, gallium or indium) and a group II species (such as beryllium, magnesium or calcium), otherwise referred to herein as a eutectic mixture, can be used as a source of the group III and group II species in an HVPE deposition of a p-type III-V epitaxial material film. In one embodiment, a eutectic mixture of a group III species and a group II species is used as a source of the group III and group II species in an HVPE deposition of a p-type group III-nitride epitaxial material film, such as beryllium- or magnesium-doped gallium nitride. In a specific embodiment, the eutectic mixture is exposed to a halide gas flow to introduce species from the eutectic mixture into a reaction chamber. The halide gas flow may be a gas flow such as, but not limited to, a Cl radical gas flow, a Cl₂ gas flow, or an HCl gas flow. In a particular embodiment, a Cl₂ gas flow is used because of the relative weakness of the Cl—Cl bond versus, e.g., an H—Cl bond.

In an embodiment, the recipe specifics of an HVPE deposition of a p-type group III-nitride epitaxial film are determined by tailoring the relative ratios of the group II and group III species in a liquid phase mechanical mixture source. In another embodiment, the recipe specifics of an HVPE deposition of a p-type group III-nitride epitaxial film are determined by tailoring the composition, concentration and flow rate of a halide gas flow to introduce species from a eutectic mixture into a reaction chamber. In an embodiment, the recipe specifics of an HVPE deposition of a p-type group III-nitride epitaxial film are determined by both tailoring the relative ratios of the group II and group III species in a liquid phase mechanical (eutectic) mixture source and by tailoring the composition, concentration and flow rate of a halide gas flow to introduce species from the eutectic mixture into a reaction chamber.

In selecting specific group II and group III species for formation of a eutectic mixture as an HVPE source, the size of the relative group II and group III species may be considered. For example, in accordance with an embodiment of the present invention, the group II and group III species are selected to have approximately the same ionic radius. However, in another embodiment, the group II species, which will ultimately be a substituting dopant in a III-V film, is selected to have a smaller ionic radius than both the group III species and the group V species. In accordance with an embodiment of the present invention, the group II species substitutes certain ones of the group III species in a group III-nitride epitaxial film, as opposed to merely being incorporated interstitially into the group III-nitride epitaxial film. As examples of ionic radii for certain group II and group III species, in accordance with an embodiment of the present invention, Be²⁺ is 0.34 Å, Mg²⁺ is 0.74 A, Ca²⁺ is 1.04 Å, B³⁺ is 0.20 Å, Al³⁺ is 0.57 Å, Ga³⁺ is 0.62 Å and In³⁺ is 0.92 Å. It is to be understood that the list of species above for which ionic radii are provided represents only an illustrative list and is by no means limited to those species listed.

In accordance with an embodiment of the present invention, atoms with tetrahedral radii close to those of Ga (or Al or In, depending on the particular case) on the cation side and N on the anion side are most suitable to act as donors or acceptors for that portion of the III-V film that is substituted. In one embodiment, the difference in radii is selected to be below approximately 10% in order to have good solubility in Ga (or Al or In, respectively) sub-lattices. In a specific embodiment, electronic state and radius are the most important criteria for selecting dopants. In one embodiment, the difference in radii is selected to be below approximately 10% in order to have good solubility in the nitrogen or other group V sub-lattices. For example, in a particular embodiment, an element from group (IV) with close radius is selected to be a donor and an element from group (VI) is selected to be an acceptor.

A selected dopant species and its relative concentration may determine the conductivity type and the free carrier concentration of a semiconductor film. For example, employment of both conductivity types (e.g., n-type and p-type) in a single material makes possible the formation of a p-n junction, which may be a basic requirement for types of electronic and optoelectronic devices, and for group III-nitrides materials in such devices in particular. Doping level control may be important for proper device operation and performance, and may determine turn-on and operating voltages, parameters of contacts, current injection efficiency and current spreading, to name a few.

In accordance with an embodiment of the present invention, group II elements predominantly occupy group III sites in a III-V film, due to the valence electron configuration of the group II and III species, and thus can be used to provide p-type group III-nitride materials. In another embodiment, group IV elements or species (such as carbon, silicon or germanium) are provided to occupy a group III site in a III-V material to provide an n-type group III-nitride material. However, in another embodiment, in the case of occupying an anion or group V site (such as a nitrogen site, a phosphorous site, an arsenic site or an antimony site), a p-type material is formed. Group IV species may be unique due to the option of substituting either a cation or anion site in a III-V material, resulting either in an excess of electrons (n-type) or a deficit of electrons (p-type). In another embodiment, group VI species (such as oxygen, sulfur, selenium or tellurium) species are provided as n-type dopants by substituting anion sites in a III-V material film.

As described above, another criteria which may be taken into account is atom or ion size and, so, the tetrahedral radii need to be known. In an embodiment, the atomic size is selected to be close for aluminum, gallium or indium, in the case of group III species and close to nitrogen in the case of group V species. Stability of the dopant bonds at a selected growth temperature may be an important factor as well. In an embodiment, two key dopants for group III-nitride materials are magnesium and silicon, for p-type and n-type doping, respectively. Often, SiH₄ or Si₂H₆ is used as a source of silicon, and Cp₂Mg is used as a source of magnesium. However, in an embodiment, selection of a variety of species is poor due to the relatively few number of compounds which satisfy all deposition criteria, with one major limitation being the need for a low vapor pressure.

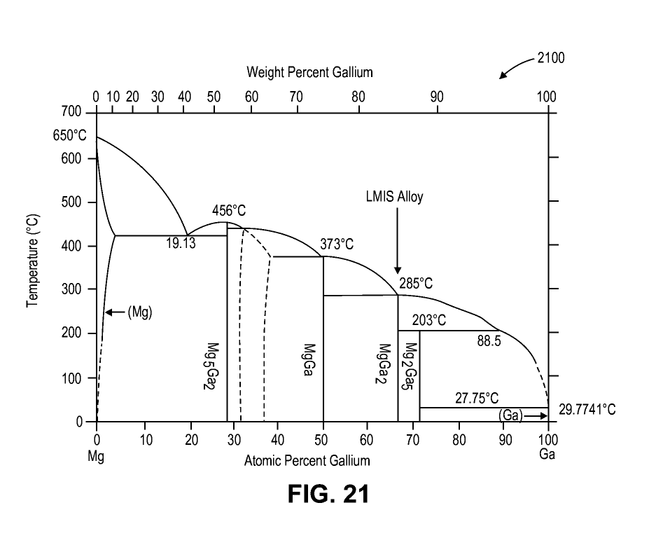

FIG. 21 illustrates an exemplary magnesium-gallium (Mg—Ga) phase diagram 2100 used for selecting an appropriate eutectic mixture for HVPE deposition, in accordance with an embodiment of the present invention. Referring to FIG. 21, an appropriate mixture of magnesium and gallium can be used to form a magnesium:gallium (Mg—Ga) eutectic mixture. In one embodiment, gallium forms not only simple eutectics with magnesium, but also several inter-metallic compounds.

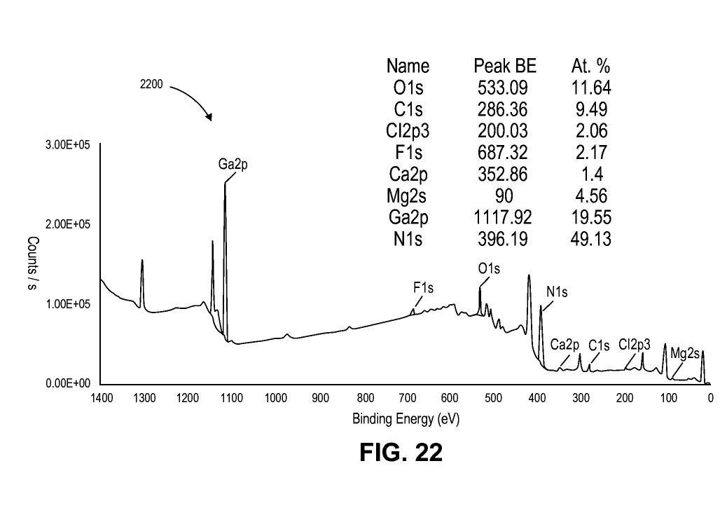

In accordance with an embodiment of the present invention, a eutectic mixture determined and selected from phase diagram 2100 is used as a metal source in an HVPE process to provide p-type gallium nitride, where magnesium is included as the p-type dopant. As an example, in one embodiment, a simple Ga—Mg eutectic was synthesized with 4W% Mg and used as p-dopant source. In a specific embodiment, the growth temperature of the p-type gallium nitride is approximately in the range of 600-1100° C., the Mg—Ga eutectic source was maintained at a temperature approximately in the range of 500-800° C., and the growth pressure is approximately in the range of 100-760 Torr. In a particular embodiment, a Cl₂ flow above the Ga—Mg source is approximately in the range 5-200 sccm and provides a growth rate of p-type gallium nitride approximately in the range of 150-200 microns per hour. In another particular embodiment, an additional Cl₂ flow approximately in the range of 5-100 sccm is used to enhance chloride formation and to optimize a deposition and etch equilibrium. In one embodiment, an inert gas such as, but not limited to, argon or helium is used in addition to the Cl₂ flow. In one embodiment, the nitrogen source for the nitride aspect of the film is a precursor such as, but not limited to, ammonia (NH₃), dinitrogen (N₂), nitrogen radical (N), or a hydrazine. FIG. 22 depicts an XPS spectrum 2200 confirming that magnesium incorporation was achieved in a gallium nitride film, in accordance with an embodiment of the present invention. Referring to FIG. 22, in one embodiment, a magnesium concentration is approximately 4.56 atomic percent.

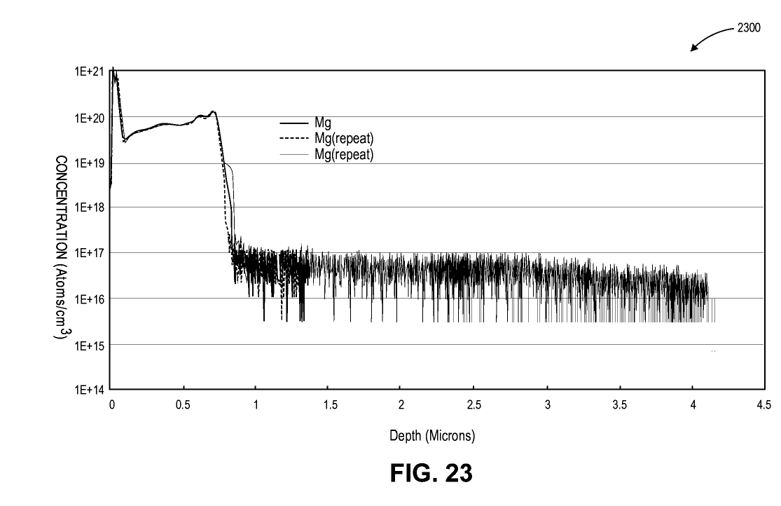

A doping profile in a grown structure may be measured by SIMS. FIG. 23 is a SIMS spectrum 2300 representative of a depth profile in a magnesium-doped p-type gallium nitride film formed from a gallium:magnesium eutectic, in accordance with an embodiment of the present invention. Referring to FIG. 23, a SIMS depth profile of magnesium-doped gallium nitride reveals a doping level of approximately 10²⁰ atom/cm³.

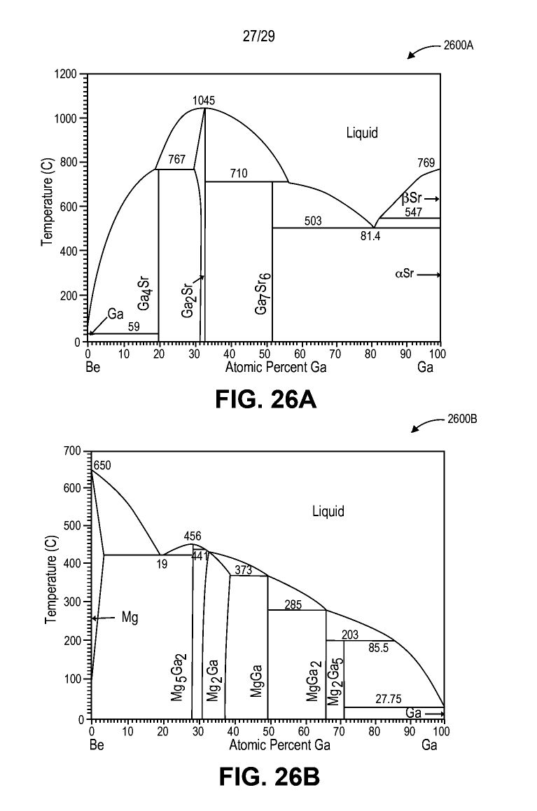

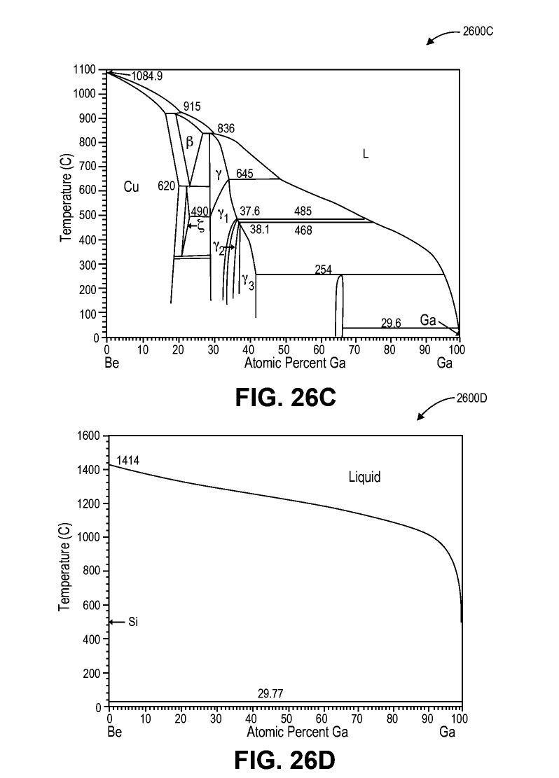

It is to be understood that embodiment of the present invention are not limited to the above listed and/or described species. For example, in an embodiment, the following metals may be used for p-type doping using Ga—metal eutectics: Cu(I), Be, Mg, Ca, Sr, Ba, Ti, Co, Ni, Zn, Cd, Hg, Se(II), Te(II), or Sn(II). In another embodiment, for n-type, a gallium:silicon (Ga—Si) eutectic is used, as described below in association with FIG. 26D. Other possible elements for n-type doping may include the use of selenium or tellurium in a gallium eutectic, when the dopant substitution is with the nitrogen portion of the nitride film.

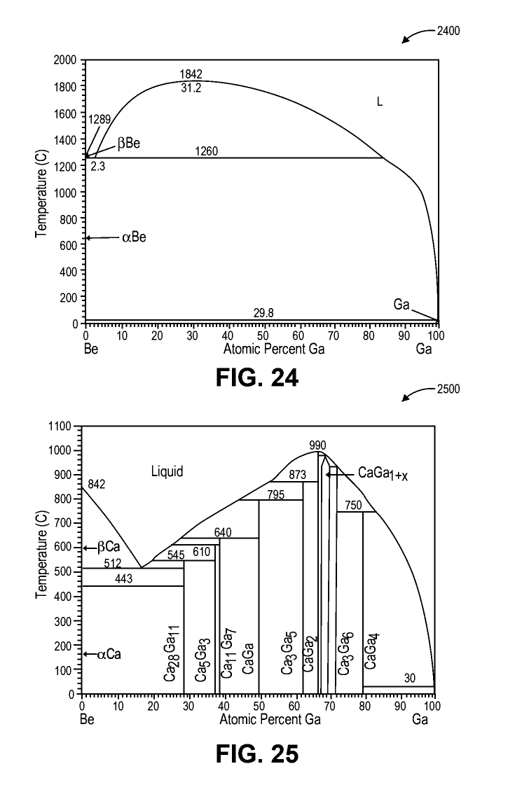

As an example of data or tools that may be used to determine optimal and/or workable conditions for forming a gallium-metal eutectic, phase diagrams may be generated and evaluated. FIG. 24 illustrates a temperature-composition phase diagram 2400 for mechanical mixtures of gallium with beryllium, in accordance with an embodiment of the present invention. FIG. 25 illustrates a temperature-composition phase diagram 2500 for mechanical mixtures of gallium with calcium, in accordance with an embodiment of the present invention. FIGS. 26A-26D illustrate temperature-composition phase diagrams 2600A-2600D for mechanical mixtures of gallium with strontium, magnesium, copper, or silicon, respectively, in accordance with an embodiment of the present invention.

In accordance with an embodiment of the present invention, the metal species used in a eutectic mixture for an HVPE source are converted to chlorides as part of the deposition process. In one embodiment, the vapor pressure of the resulting chlorides plays a role in the deposition. As an example of data or tools that may be used to determine optimal and/or workable conditions for using a gallium-metal eutectic in an HVPE process where halide species are generated, plots of pressure as a function of temperature for halide products may be generated and evaluated. For example, taken from plots of pressure (in mm Hg) as a function of temperature (in degrees Celsius), ranges for various chloride species include approximately 10-50000 mm Hg versus approximately 80-450 degrees Celsius for GaCl₃, approximately 10-3000 mm Hg versus approximately 10-190 degrees Celsius for AlCl₃, approximately 10-50000 mm Hg versus approximately (−70)−230 degrees Celsius for SiCl₄, approximately 10-1000 mm Hg versus approximately 290-490 degrees Celsius for BeCl₂, approximately 10-800 mm Hg versus approximately 600-970 degrees Celsius for CdCl₂, approximately 10-1000 mm Hg versus approximately 400-1500 degrees Celsius for CuCl, approximately 10-900 mm Hg versus approximately 750-1450 degrees Celsius for MgCl₂, approximately 10-950 mm Hg versus approximately 430-730 degrees Celsius for ZnCl₂, or approximately 10-750 mm Hg versus approximately 820-1050 degrees Celsius for CoCl₂, respectively, in accordance with an embodiment of the present invention. Taken from a plot of pressure (in mm Hg) as a function of temperature (in degrees Celsius), ranges for the chlorine molecule, Cl₂, are approximately 10-80000 mm Hg versus approximately (−100)−150 degrees Celsius, in accordance with an embodiment of the present invention. In one embodiment, the data for Cl₂ is included in the case that an additional chlorine flow is used in the deposition.

It is to be understood that the sources and methods described herein are not limited to the formation of binary group III-nitride films. For example, in accordance with an embodiment of the present invention, a source or method described herein may be used to provide a doped ternary group III-nitride film, such as but not limited to a doped InGaN, AlGaN, or InAlN film. In accordance with another embodiment of the present invention, a source or method described herein may be used to provide a doped quaternary group III-nitride film, such as but not limited to a doped GaInAlN film.

It is also to be understood that, with respect to dopants, in accordance with an embodiment of the present invention, there may be a particular benefit to using magnesium as a dopant. For example, in one embodiment, since no H₂ is used, enhanced magnesium incorporation may be achieved because there is no availability of Mg-H formation. Furthermore, in one embodiment, no thermal annealing after the HVPE growth is required to activate such a Mg—H complex. However, embodiments of the present invention are by no means limited to magnesium as a dopant species.

In an embodiment, a doped III-V layer formed from a eutectic mixture is used in the fabrication of a light-emitting diode (LED) device, such as those devices described above.

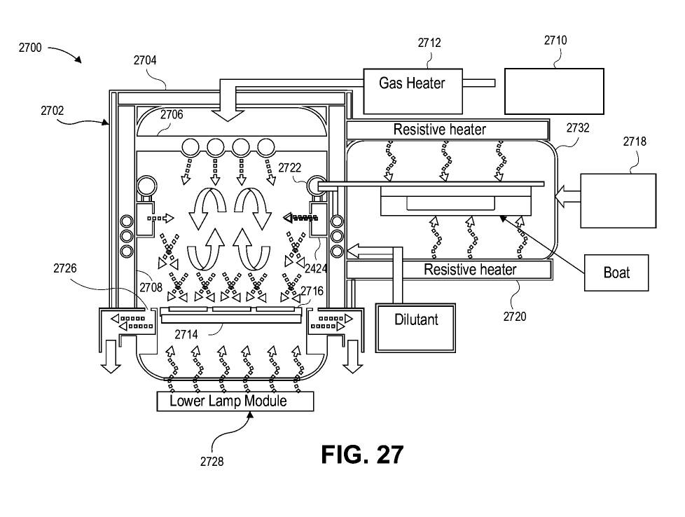

An example of a HVPE deposition chamber which may be utilized to deposit group III-nitrides or similar films in accordance with embodiments of the present invention is illustrated and described with respect to FIG. 27.

FIG. 27 is a schematic view of an HVPE apparatus 2700 according to one embodiment. The apparatus includes a chamber 2702 enclosed by a lid 2704. Processing gas from a first gas source 2710 is delivered to the chamber 2702 through a gas distribution showerhead 2706. In one embodiment, the gas source 2710 may comprise a nitrogen containing compound. In another embodiment, the gas source 2710 may comprise ammonia. In one embodiment, an inert gas such as helium or diatomic nitrogen may be introduced as well either through the gas distribution showerhead 2706 or through the walls 2708 of the chamber 2702. An energy source 2712 may be disposed between the gas source 2710 and the gas distribution showerhead 2706. In one embodiment, the energy source 2712 may comprise a heater. The energy source 2712 may break up the gas from the gas source 2710, such as ammonia, so that the nitrogen from the nitrogen containing gas is more reactive.

To react with the gas from the first source 2710, precursor material may be delivered from one or more second sources 2718. The one or more second sources 2718 may comprise a eutectic mixture. The precursor may be delivered to the chamber 2702 by flowing a reactive gas over and/or through the precursor or eutectic mixture in the precursor source 2718. In one embodiment, the reactive gas may comprise a chlorine containing gas such as diatomic chlorine. The chlorine containing gas may react with the precursor source to form a chloride. In order to increase the effectiveness of the chlorine containing gas to react with the precursor or eutectic mixture, the chlorine containing gas may snake through the boat area in the chamber 2732 and be heated with the resistive heater 2720. By increasing the residence time that the chlorine containing gas is snaked through the chamber 2732, the temperature of the chlorine containing gas may be controlled. By increasing the temperature of the chlorine containing gas, the chlorine may react with the precursor or eutectic mixture faster. In other words, the temperature is a catalyst to the reaction between the chlorine and the precursor or eutectic mixture.

In order to increase the reactiveness of the precursor or eutectic mixture, the precursor or eutectic mixture may be heated by a resistive heater 2720 within the second chamber 2732 in a boat. The chloride reaction product may then be delivered to the chamber 2702. The reactive chloride product first enters a tube 2722 where it evenly distributes within the tube 2722. The tube 2722 is connected to another tube 2724. The chloride reaction product enters the second tube 2724 after it has been evenly distributed within the first tube 2722. The chloride reaction product then enters into the chamber 2702 where it mixes with the nitrogen containing gas to form a nitride layer on the substrate 2716 that is disposed on a susceptor 2714. In one embodiment, the susceptor 2714 may comprise silicon carbide. The nitride layer may comprise doped gallium nitride or doped aluminum nitride for example. The other reaction products, such as nitrogen and chlorine, are exhausted through an exhaust 2726.

Thus, sources for and methods of doping group III-nitrides by hydride vapor phase epitaxy using group III-metal eutectics have also been disclosed. In accordance with an embodiment of the present invention, a source is provided for HVPE deposition of a p-type group III-nitride epitaxial film. The source includes a liquid phase mechanical (eutectic) mixture of a group III species and another species such as, but not limited to, a group II species, a group I species, or a species not in group I or II but having a valence charge of one or two. In one embodiment, for the source, the group III species is gallium, the other species is beryllium or magnesium, and the p-type group III-nitride epitaxial film is a beryllium- or magnesium-doped gallium nitride epitaxial film. In another embodiment of the present invention, a method is provided for performing HVPE deposition of a p-type group III-nitride epitaxial film. The method includes using a liquid phase mechanical (eutectic) mixture of a group III species and another species such as, but not limited to, a group II species, a group I species, or a species not in group I or II but having a valence charge of one or two. In one embodiment, for the method, the group III species is gallium, the other species is beryllium or magnesium, and the p-type group III-nitride epitaxial film is a beryllium- or magnesium-doped gallium nitride epitaxial film. In accordance with another embodiment of the present invention, a source is provided for HVPE deposition of an n-type group III-nitride epitaxial film. The source includes a liquid phase mechanical (eutectic) mixture of a group III species and a group IV species or a group VI species. In one embodiment, for the source, the group III species is gallium and the n-type group III-nitride epitaxial film is a group IV- or group VI-doped gallium nitride epitaxial film. In another embodiment, a method is provided for performing HVPE deposition of an n-type group III-nitride epitaxial film. The method includes using a liquid phase mechanical (eutectic) mixture of a group III species and a group IV species or a group VI species. In one embodiment, for the method, the group III species is gallium and the n-type group III-nitride epitaxial film is a group IV- or group VI-doped gallium nitride epitaxial film.

1. A semiconductor device comprising:
an active region including one or more active layers, wherein the one or more active layers comprise one or more quantum wells and one or more barrier layers, wherein some or all of said one or more active layers are p type doped.

2. The semiconductor device of claim 1, wherein the p type dopant comprises an element having at least two valence electrons.

3. The semiconductor device of claim 2, wherein the element is selected from the group consisting of Mg, Co, and Zn.

4. The semiconductor device of claim 1, wherein the active region is between an n type contact layer and an electron blocking layer.

5. The semiconductor device of claim 4, wherein one or more of the barrier layers nearest the n type contact layer are n type doped and one or more of the barrier layers nearest the electron blocking layer are p type doped.

6. The semiconductor device of claim 5, wherein the barrier layers nearest the n type contact layer are n type doped in a graded fashion with the barrier layer nearest the n type contact layer having the highest n type conductivity level and each further barrier layer having a higher n type conductivity level than the next further barrier layer, further wherein the barrier layers nearest the electron blocking layer are p type doped in a graded fashion with the barrier layer nearest the electron blocking layer having the highest p type conductivity level and each further barrier layer having a higher p type conductivity level than the next further barrier layer.

7. The semiconductor device of claim 5, wherein one or more of the barrier layers in between the n type contact layer and the electron blocking layer are undoped.

8. The semiconductor device of claim 6, wherein one or more of the barrier layers in between the n type contact layer and the electron blocking layer are undoped.

9. The semiconductor device of claim 4, further including a substrate wherein a buffer/transition layer is deposed on top of the substrate, the n type contact layer is deposed on top of the buffer/transition layer, the active region is deposed on top of the n type contact layer, the electron blocking layer is deposed on top of the active region and a p type contact layer is deposed on top of the electron blocking layer.

10. A method comprising:
forming a p type doped group III film using one or more alloy sources, wherein the one or more alloy sources comprise an alloy of a dopant and one or more group III materials.

11. The method of claim 10, wherein the dopant comprises an element having at least two valence electrons.

12. The method of claim 11, wherein the element is selected from the group consisting of Mg, Co, and Zn.

13. The method of claim 10, wherein the one or more group III materials is selected from the group consisting of In, Ga, and Al.

14. The method of claim 10, wherein the alloy of the dopant and the one or more group III materials is a eutectic of the dopant and the one or more group III materials.

15. An integrated processing system for manufacturing semiconductor devices, comprising:
a cluster tool comprising:
one or more walls that form a transfer region;
a robot disposed in the transfer region;
one or more processing chambers operable to form one or more compound semiconductor layers on a substrate that are in transferable communication with the transfer region wherein the one or more processing chambers comprise a hydride vapor phase epitaxy (HVPE) chamber having a source boat with an alloy of a first material and of a second material;
a loadlock chamber in transferable communication with the transfer region, the loadlock chamber having an inlet valve and an outlet valve to receive at least one substrate into a vacuum environment, and
a load station in communication with the loadlock chamber, wherein the load station comprises a conveyor tray movable to convey a carrier plate loaded with one or more substrates into the loadlock chamber.

16. The system of claim 15, wherein the one or more processing chambers comprise a metalorganic chemical vapor deposition (MOCVD) chamber.

17. The system of claim 15, wherein the alloy is a eutectic alloy of the first material and the second material wherein the first material is Mg and the second material is Ga.

18. A source for HVPE deposition of a p-type group III-nitride epitaxial film, the source comprising:
a liquid phase mechanical (eutectic) mixture of a group III species; and
another species selected from the group consisting of a group II species, a group I species, and a species not in group I or II but having a valence charge of one or two.

19. The source of claim 18, wherein the group III species is gallium, the other species is beryllium or magnesium, and the p-type group III-nitride epitaxial film is a beryllium- or magnesium-doped gallium nitride epitaxial film.

20. The source of claim 18, wherein the other species is a group IV or a group VI species with a valance charge of two.

21. A source for HYPE deposition of an n-type group III-nitride epitaxial film, the source comprising:
a liquid phase mechanical (eutectic) mixture of a group III species; and
a group IV or group VI species.

22. The source of claim 21, wherein the group III species is gallium and the n-type group III-nitride epitaxial film is a group IV- or a group VI-doped gallium nitride epitaxial film.

23. A method comprising:
forming a liquid phase mechanical (eutectic) mixture of a group III species and another species selected from the group consisting of a group II species, a group I species, and a species not in group I or II but having a valence charge of one or two; and
performing HYPE deposition of a p-type group III-nitride epitaxial film using the eutectic mixture.

24. The method of claim 23, wherein the group III species is gallium, the other species is beryllium or magnesium, and the p-type group III-nitride epitaxial film is a beryllium- or magnesium-doped gallium nitride epitaxial film.

25. The method of claim 23, wherein the other species is a group IV or a group VI species with a valance charge of two.

26. A method comprising:
forming a liquid phase mechanical (eutectic) mixture of a group III species and a group IV or group VI species; and
performing HYPE deposition of an n-type group III-nitride epitaxial film using the eutectic mixture.

27. The method of claim 26, wherein the group III species is gallium and the n-type group III-nitride epitaxial film is a group IV- or a group VI-doped gallium nitride epitaxial film.

28. A method comprising:
forming a liquid phase mechanical (eutectic) mixture of gallium and another species; and
performing HYPE deposition of a gallium nitride-based epitaxial film using the eutectic mixture.

29. The method of claim 28, wherein the gallium nitride-based epitaxial film is a semiconducting film.

30. The method of claim 28, wherein the gallium nitride-based epitaxial film is a semi-insulating film.
